(19) United States
(12) Patent Application Publication
(10) Pub. No.: US 2025/0140642 A1
(43) Pub. Date: May 1, 2025

(54) INTEGRATED CIRCUIT DEVICE WITH THERMOELECTRIC COOLING

(71) Applicant: Taiwan Semiconductor Manufacturing Company, Ltd., Hsinchu (TW)

(72) Inventors: Cheng-Ming Lin, Kaohsiung City (TW); Che Chi Shih, Taoyuan City (TW); Wei-Yen Woon, Taoyuan City (TW); Szuya Liao, Hsinchu (TW); Isha Datye, Hsinchu (TW); Sam Vaziri, San Jose, CA (US); Po-Yu Chen, Baoshan Township (TW); Cheng Hung Wu, Hsinchu County (TW); Wei-Pin Changchien, Taichung City (TW); Xinyu Bao, Fremont, CA (US)

(21) Appl. No.: 18/597,045

(22) Filed: Mar. 6, 2024

Related U.S. Application Data
(60) Provisional application No. 63/594,074, filed on Oct. 30, 2023.

(51) Int. Cl. H01L 23/38; H01L 21/48; H01L 23/00; H01L 23/48; H01L 23/528; H01L 23/538; H01L 25/065

(52) U.S. Cl. CPC H01L 23/38; H01L 21/4857; H01L 23/481; H01L 23/5286; H01L 23/5383; H01L 23/5386; H01L 23/5389; H01L 24/19; H01L 24/20; H01L 25/0657; H01L 2224/214; H01L 2225/06506; H01L 2225/06544; H01L 2225/06568; H01L 2225/06589

(57) ABSTRACT

A thermoelectric cooler (TEC) is positioned to move heat away from a hot spot on a semiconductor chip and toward a dielectric substrate. This approach to thermal management is particularly effective when used in conjunction with a buried rail and back side power delivery. The TEC may be in a layer that contains solder connections be between two device layers an IC package. Alternatively, the TEC may be in a metal interconnect structure over the semiconductor substrate such as in a passivation stack at the top of the metal interconnect structure. TECs at either of these locations may be formed by wafer-level processing.

### REFERENCE TO RELATED APPLICATION

This application claims the benefit of U.S. Provisional Application No. 63/594,074, filed on Oct. 30, 2023, the contents of which are hereby incorporated by reference in their entirety.

### BACKGROUND

As semiconductor technology continues to advance, there is an ever-increasing demand for higher-performance devices with smaller form-factors. To meet these demands, three-dimensional integrated circuit (3D-IC) technology has emerged as a promising solution. 3D-IC technology allows multiple integrated circuit (IC) layers to be vertically stacked within a single package. This approach offers increased device density and performance while reducing the overall footprint.

Heat, if not properly managed, can degrade the performance of IC devices, reduce their lifespan, or even cause catastrophic failure. In 3D-IC devices, thermal management is made more difficult due to the stacking and close proximity of multiple active layers and interconnects. Existing thermal management techniques for 3D-IC devices include the use of heat sinks, fans, and thermal interface materials (TIMs).

### BRIEF DESCRIPTION OF THE DRAWINGS

Aspects of the present disclosure are best understood from the following detailed description when read with the accompanying figures. In accordance with standard industry practice, features are not drawn to scale. Moreover, the dimensions of various features within individual drawings may be arbitrarily increased or reduced relative to one-another to facilitate illustration or provide emphasis.

FIG. 1 illustrates a cross-sectional view of an apparatus including a 3D integrated circuit (3D-IC) device according to an embodiment of the present disclosure.

FIG. 2 illustrates an expanded view of a portion of FIG. 1.

FIG. 3 is a perspective view of a thermoelectric cooler (TEC).

FIG. 4 illustrates a cross-sectional view of an apparatus with a 3D-IC according to another embodiment.

FIG. 5 illustrates an expanded view of a portion of a chip in FIG. 4.

FIG. 6A illustrates a variation on the chip of FIG. 5 in accordance with another embodiment.

FIG. 6B illustrates a variation on the chip of FIG. 5 in accordance with another embodiment.

FIG. 7 illustrates an apparatus with an IC device according to another embodiment.

FIG. 8 illustrates an expanded view of a portion of a chip in FIG. 7.

FIG. 9 illustrates a variation on the chip of FIG. 8 in accordance with another embodiment.

FIG. 10 illustrates an apparatus with an IC device according to another embodiment.

FIG. 11 illustrates an expanded view of a portion of a chip in FIG. 10.

FIG. 12 illustrates a variation on the chip of FIG. 10 in accordance with another embodiment.

FIGS. 13-42 illustrate a process in accordance with some aspects of the present disclosure.

FIGS. 43-46 illustrate a variation of the process of FIGS. 13-42 in accordance with another embodiment.

FIG. 47 illustrates a wafer according to an embodiment of the present disclosure.

FIG. 48 illustrates a die of a wafer in accordance with another embodiment.

FIGS. 49-51 illustrate a process in accordance with another embodiment.

FIG. 52-55 provide flow charts of processes in accordance with various embodiments of the present disclosure.

### DETAILED DESCRIPTION

The present disclosure provides many different embodiments, or examples, for implementing different features of this disclosure. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact and may also include embodiments in which additional features may be formed between the first and second features, such that the first and second features may not be in direct contact.

Spatially relative terms, such as “beneath,” “below,” “lower,” “above,” “upper”, and the like, may be used herein to describe one element or feature's relationship to another element(s) or feature(s) as illustrated in the figures. These spatially relative terms are intended to encompass different orientations of the device or apparatus in use or operation in addition to the orientation depicted in the figures. The device or apparatus may be otherwise oriented (rotated 90 degrees or at other orientations) and the spatially relative descriptors used herein may be interpreted accordingly. Terms “first”, “second”, “third”, “fourth”, and the like are merely generic identifiers and, as such, may be interchanged in various embodiments. For example, while an element (e.g., an opening) may be referred to as a “first” element in some embodiments, the element may be referred to as a “second” element in other embodiments.

A heat sink with a fan or liquid coolant may provide sufficient cooling for an IC package as a whole while not providing sufficient cooling locally. 3D-IC packages are particularly susceptible to this type of non-uniform heat distribution and local hot spot formation. Some aspects of the present disclosure relate to solving this problem using a thermoelectric cooler (TEC) to pump heat within an apparatus that includes an IC package.

In some embodiments, the TEC is positioned to move heat away from a chip that comprises a semiconductor substrate and toward a dielectric substrate. The dielectric substrate may be that of an interposer or a carrier substrate. In some embodiments, the dielectric substrate is a the substrate of a printed circuit board. Although these dielectric substrates are not ordinarily thought of as heat sinks, they may be operative as heat sinks due to their large size in comparison to the size of a particular hot spot.

Some aspects of the present disclosure relate to placing a TEC between two substrates in an apparatus that includes an IC package. The TEC may be configured so as to pump heat away from a semiconductor substrate and toward a dielectric substrate. In some embodiment, the TEC is in a metal interconnect structure over the semiconductor substrate. In some embodiment, the TEC is in a passivation stack at the top of the metal interconnect structure. In some embodiment, the TEC is between two device layers. In some embodiment, the TEC is in a layer that contains solder connections. There may be a plurality of TECs and two or more of the TECs may be stacked so as to increase a temperature differential.

Some aspects of the present disclosure relate to a TEC disposed in a passivation stack at the top of a metal interconnect structure on a chip. The TEC may be integrated into the passivation stack during wafer level processing. The chip may be packaged so that the passivation stack faces another substrate or device layer. In some embodiments, a bottom heat conductive dielectric layer is formed below the TEC. The bottom heat conductive dielectric layer facilitates transporting heat to a cold side of the TEC, particularly when the TEC occupies only a portion of the passivation stack area. The TEC may occupy only a portion of the passivation stack area to leave room for other structures in the passivation stack such as vias. In some embodiments, a top heat conductive dielectric layer is formed above the TEC. The top heat conductive dielectric layer facilitates spreading heat from a top side of the TEC along and subsequently across an interface with a second substrate.

Some aspects of the present disclosure relate to a TEC disposed within a layer that contains solder connections between the two substrates. It has been found that these solder connection layers can be a significant barrier to heat transport. In some embodiments, the TEC is disposed between solder bumps. The solder bumps may be in an array. In some embodiments, the array is a ball grid array (BGA). In some embodiments, the solder bumps are in a controlled collapse chip connection (C4) array. For the BGA, the TEC is placed during packaging. For the C4 array, the TEC may be formed during wafer-level processing.

Some aspects of the present disclosure relate to an IC device in which semiconductor devices on the front side of a semiconductor substrate are supplied with power from the back side of the semiconductor substrate. A buried rail may be provided on the front side so that the power does not need to be routed through a front side metal interconnect structure. The buried rail may receive power from a power rail on the back side by means of a through substrate via (TSV). A TEC is positioned to pump heat away from the back side. In some embodiments, the TEC is in a passivation stack at the top of a back side metal interconnect structure. In some embodiments, the TEC is within a layer of solder connections on the back side. Providing power from the back side in combination with a TEC that pumps heat away from the back side provides an effective solution for thermal management in many applications.

Some aspects of the present disclosure relate to a method of manufacturing an IC device with a TEC. The method begins with front-end-of-line (FEOL) processing of a semiconductor substrate. A plurality of metallization layers are then formed over one or the other side of the semiconductor substrate. A first connection layer including first wires is formed over an uppermost metallization layer of the plurality of metallization layers. A dielectric layer is then formed over the first connection layer. First vias of semiconductor having P-type doping and second vias with semiconductor having N-type doping are formed in the dielectric layer. A second connection layer including second wires is then formed. The first wires and the second wires connect groups of the first vias and the second vias in series so that one or more TECs are formed.

In some embodiments, a bottom heat conductive dielectric layer is formed immediately before the first connection layer. In some embodiments, the first connection layer includes a heat conductive dielectric between the first wires. In some embodiments, the second connection layer includes a heat conductive dielectric between the second wires. In some embodiments, a top heat conductive dielectric layer is formed immediately after the second connection layer.

In some embodiments, the TECs are formed above a pad layer. The first dielectric is etched from around the TECs to form openings and solder bumps are deposited in the openings. In some embodiments, the semiconductor substrate is a wafer that is diced after depositing these solder bumps. Each die may then contain one or more of the TECs.

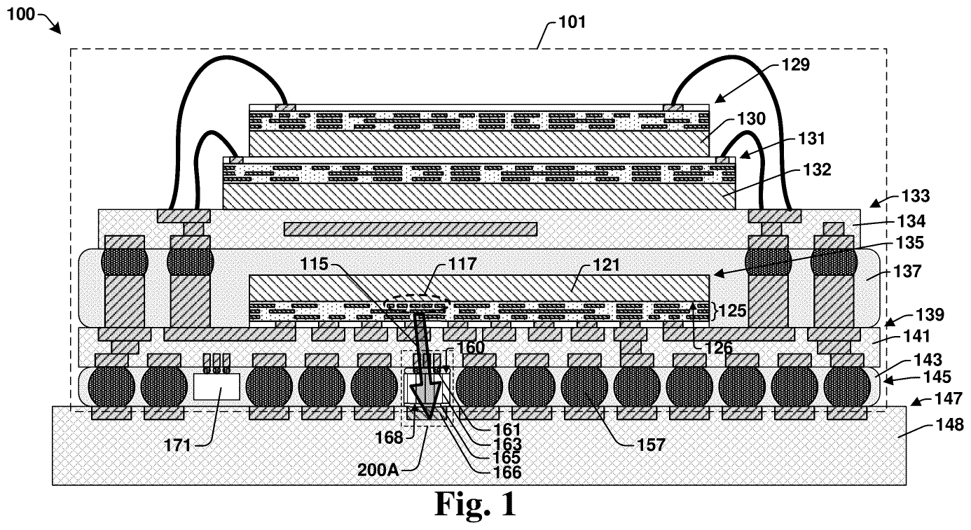

FIG. 1 illustrates an apparatus 100 with a 3D-IC device 101 in accordance with some embodiments. The 3D-IC device is mounted to a printed circuit board 147. The 3D-IC device 101 has a plurality of device layers including a first routing layer 139, a first chip 135, a second routing layer 133, a second chip 131, and a third chip 129. The printed circuit board 147 and each of these device layers includes a substrate. The printed circuit board 147 comprises a board substrate 148. The first routing layer 139 comprises a first package substrate 141. The first chip 135 comprises a first semiconductor substrate 121. The second routing layer 133 comprises a second package substrate 134. The second chip 131 comprising a second semiconductor substrate 132. The third chip 129 comprising a third semiconductor substrate 130. A high thermal conductivity underfill 137 may fill space between the second routing layer 133 and the first chip 135.

The first package substrate 141, the second package substrate 134, and the board substrate 148 are dielectric substrates. A dielectric substrate may be, for example, an organic polymer substrate, the like, or some other suitable dielectric material. Examples of organic polymer substrate materials include, without limitation, polyimide, polytetrafluoroethylene, epoxies, and the like. An epoxy may be one formed from Bismaleimide-Triazine resin (BT-resin), some other epoxy resin, or the like. A dielectric substrate may be a laminate and may be reinforced with glass cloth, fiberglass, or the like.

A hot spot 117 may tend to form in the first chip 135 in an area by the front side 126 of the first semiconductor substrate 121 or within the metal interconnect structure 125 on the front side 126. Heat movement upward from the hot spot 117 may be inhibited by one or more of the following structures: the first semiconductor substrate 121, the high thermal conductivity underfill 137, the second routing layer 133, the second chip 131, and the third chip 129. Heat movement in that direction may be further inhibited by heat generation in the second chip 131 and the third chip 129.

In accordance with the present disclosure, the primary path 115 of heat removal from the hot spot 117 is downward to the printed circuit board 147. To reach the printed circuit board 147, the heat passes through the first routing layer 139 and the solder connection layer 145. The solder connection layer 145 includes solder bumps 157 which form a ball grid array (BGA). The solder connection layer 145 may also include thermal paste 143.

In accordance with the presence disclosure, a TEC 163 is disposed in the path 115 so as to drive heat transfer from the hot spot 117 to the printed circuit board 147. In some embodiments, the TEC 163 is disposed in the solder connection layer 145. When provided with power, the TEC 163 transfers heat from a cold side 160 that faces the hot spot 117 to a hot side that faces the printed circuit board 147. The cold side 160 may thus be cooled. In some embodiments, the cold side 160 is cooled below an ambient temperature.

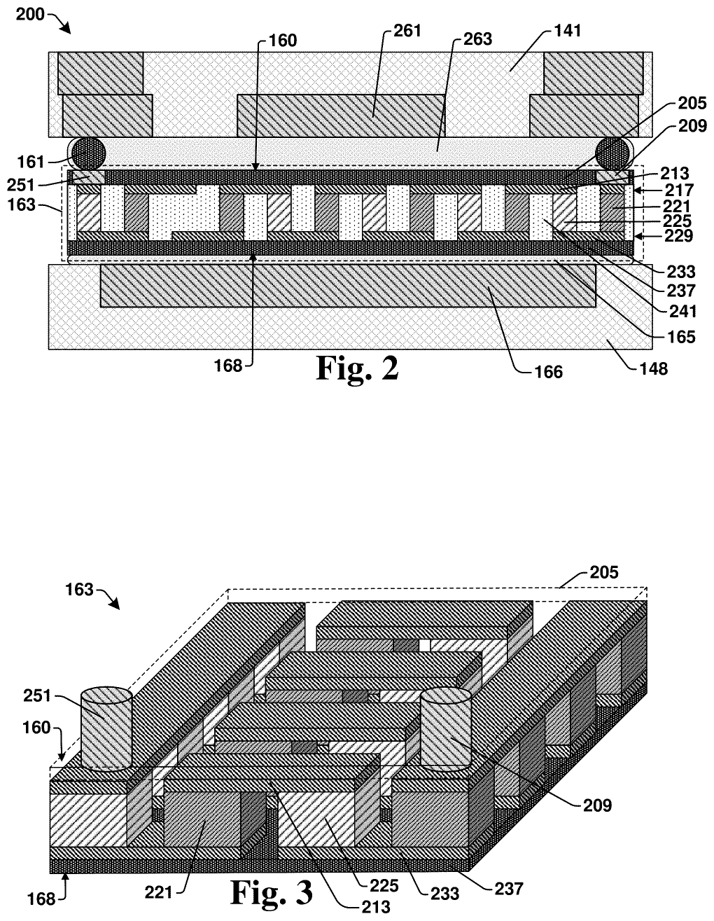

FIG. 2 provides a cross-sectional view 200 that roughly corresponds to an area 200A in FIG. 1. The area 200A is around and included the TEC 163. As shown in FIG. 2, the TEC 163 include a bottom dielectric layer 237, first wires 233 in a first wiring layer 229, N-type vias 225 and P-type vias 221 an oxide layer 241, second wires 213 in a second wiring layer 217, and a top dielectric layer 205. The N-type vias 225 and the P-type vias 221 are semiconductors with P-type doping and N-type doping respectively.

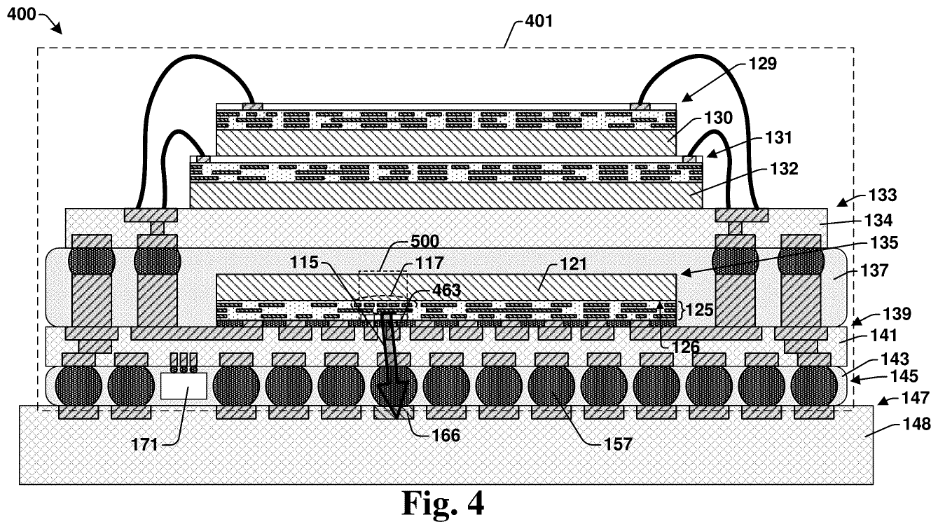

FIG. 3 illustrates a perspective view of the TEC 163 with the oxide layer 241 cut away and the top dielectric layer 205 shown in outline. As can be seen in FIG. 3, the first wires 233 and the second wires 213 connect groups of the N-type vias 225 and the P-type vias 221 is series between a first electrode 209 and a second electrode 251. When current flows from the first electrode 209 to the second electrode 251, it flows from the N-type vias 225 to the P-type vias 221 on the cold side 160. The charge carriers passing between the N-type vias 225 and the P-type vias 221 absorb heat so as to produce a cooling effect. The charge carriers pass between the P-type vias 221 to the N-type vias 225 on the hot side 168, releasing the heat absorbed. Holes in the N-type vias 225 and electrons in the P-type vias 221 carry heat from the cold side 160 to the hot side 168.

In some embodiments, one or both of the bottom dielectric layer 237 and the top dielectric layer 205 are high thermal conductivity dielectrics. In the present disclosure, a high thermal conductivity dielectric has a thermal conductivity of at least about 10 W/m-K. By comparison, silicon dioxide (SiO₂) has a thermal conductivity in the range from about 1.1 W/m-K to about 1.4 W/m-K. Crystalline silicon nitride (Si₃N₄) is an example of a high thermal conductivity dielectric and may have a thermal conductivity as high as 29 W/m-K. The silicon nitride (Si₃N₄) commonly found in semiconductor devices is amorphous and has a thermal conductivity in the range from about 2 W/m-K to about 5 W/m-K. The amorphous form is ordinarily produced because it lends itself to higher deposition rates than does the crystalline form. Also, the lower dielectric constant than of the amorphous form is usually sought after. Thermal conductivity may be varied continuously with degree of crystallinity between the purely amorphous form and a purely crystalline form.

In some embodiments, one or both of the bottom dielectric layer 237 and the top dielectric layer 205 are extremely high thermal conductivity dielectrics. An extremely high thermal conductivity dielectric has a thermal conductivity higher than purely crystalline silicon nitride (Si₃N₄), in other words, higher than 29 W/m-K. In some embodiments, the extremely high thermal conductivity dielectric has a thermal conductivity of at least about 100 W/m-K. Examples of dielectrics having a thermal conductivity of at about 100 W/m-K or more include, without limitation, aluminum nitride (AlN), crystalline boron nitride (BN), crystalline boron phosphide (BP), crystalline boron arsenide (BAs), hexagonal boron nitride (hBN), graphene, diamond, and the like. Among these example, aluminum nitride (AlN), boron nitride (BN), boron phosphide (BP), boron arsenide (BAs) have amorphous forms, crystalline forms, and forms of intermediate crystallinity. Forms with sufficient crystallinity are extremely high thermal conductivity dielectrics. With regard to the hexagonal compounds, which include hexagonal boron nitride (hBN) and graphene, the thermal conductivity depends on the form. The lateral forms (sheets) generally provide the highest thermal conductivity. In some embodiments, the extremely high thermal conductivity dielectric has a thermal conductivity of at least about 1000 W/m-K or more. This can be achieved, for example, with boron arsenide (BAs), one of the carbon-based dielectrics described above, or the like. These extremely high thermal conductivity dielectrics are particularly useful for laterally spreading heat using only thin layers.

Returning to FIG. 1, the TEC 163 may be coupled to the first routing layer 139 through solder micro-bumps 161 or the like. A passive device 171 may likewise be disposed at the level of the solder bumps 157 and coupled to the first routing layer 139. Alternatively, the TEC 163 may be coupled to the first routing layer 139 by direct connection between contact pads, in which case the TEC 163 may be bound to the first routing layer 139 by metal-to-metal bonding, dielectric-to dielectric bonding, or a combination of metal-to-metal and dielectric-to dielectric bonding. A thermal paste 165 by be applied to the hot side 168 in order to ensure good thermal contact with the printed circuit board 147.

In some embodiments, the TEC 163 is powered from the cold side 160, which in the present example means that the power comes from the first routing layer 139. Powering from the cold side 160 facilitates manufacturing. In some other embodiments, the TEC 163 is powered from the hot side 168. Powering from the hot side 168 may keep some of the heat generated when powering the TEC 163 away from the hot spot 117. Power from the printed circuit board 147 or other device layer on the hot side 168 may be provided through bond pad 166.

With reference to FIG. 2, in some embodiments the bond pad 166 or a like metal structure is disposed in the printed circuit board 147 adjacent to the hot side 168 without being electrically connected to the TEC 163. Such a metal structure may facilitate drawing heat away from the hot side 168. Likewise, in some embodiments a bond pad 261 or like metal structure not needed for wiring or bonding is disposed in the first routing layer 139 or like device layer adjacent to the cold side 160 to facilitate heat transport to the cold side 160. A thermal paste 263 may be provided between the solder micro-bumps 161 to facilitate heat transfer.

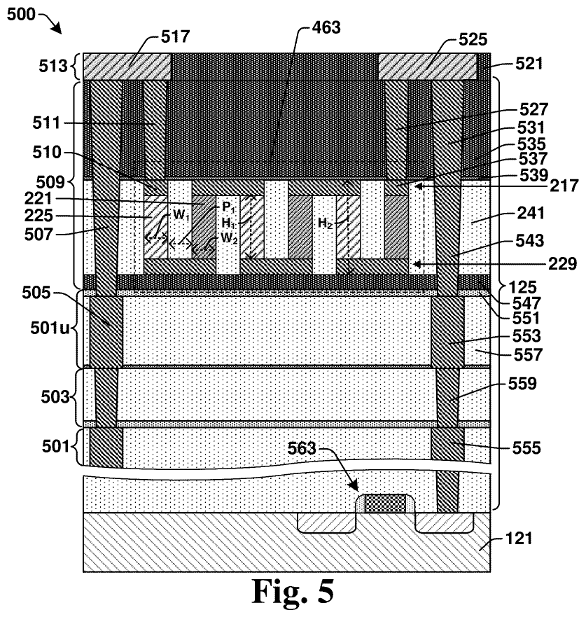

FIG. 4 illustrates an apparatus 400 that includes an 3D-IC device 401 in accordance with another embodiment. The 3D-IC device 401 is like the 3D-IC device 101 of FIG. 1 except that the 3D-IC device 401 has one or more TECs 463 rather than the TEC 163. The TECs 463 and the TEC 163 are similar in structure but are in different locations. The differences in location may dictate differences in size and power connections. The TECs 463 are disposed in the metal interconnect structure 125 on the first chip 135.

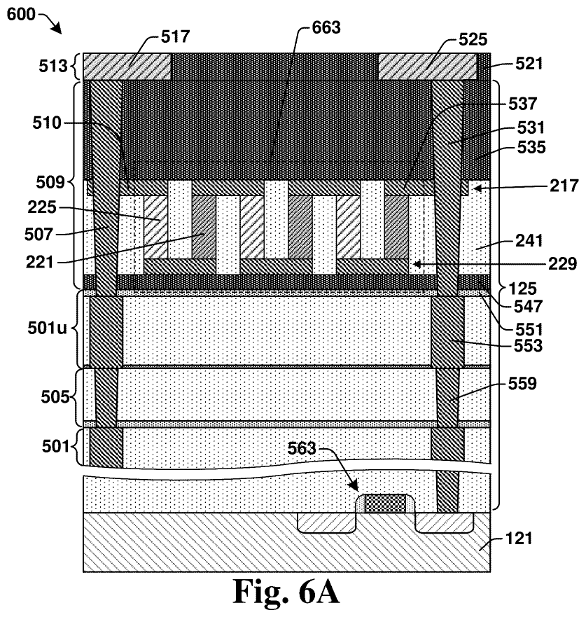

FIG. 5 illustrates a cross-sectional view of a chip 500 that may correspond to the first chip 135 in the 3D-IC device 401 of FIG. 4. As shown in FIG. 5, the chip 500 includes the metal interconnect structure 125 over the first semiconductor substrate 121. Semiconductor devices 563 are formed at on the first semiconductor substrate 121. The semiconductor devices 563 may include transistors (such as complementary metal oxide field effect transistors (MOSFETs), fin field effect transistors (finFETs), or the like), diodes, capacitors, memory cells, thyristors, resistors, the like, or any combination thereof. The metal interconnect structure 125 comprises a plurality of metallization layers 501, including an uppermost metallization layer 501u, and a plurality of vias layers 503. The metallization layers 501 contain wires 555 and the vias layers 503 contain vias 559. The TEC 463 is disposed over the uppermost metallization layer 501u.

A first contact pad 517 and a second contact pad 525 are on top of the passivation stack 509. A first via 507 passes through the passivation stack 509 to couple the first contact pad 517 to a first wire 505 in the uppermost metallization layer 501u. A second via 543 passes through the passivation stack 509 to couple the second contact pad 525 to a second wire 553 in the uppermost metallization layer 501u.

The TEC 463 is disposed in the passivation stack 509. The TEC 463 comprises a first electrode 510 and a second electrode 537, which may be wires in the second wiring layer 217. A third via 511 couples the first contact pad 517 to the first electrode 510. A fourth via 527 couples the second contact pad 525 to the second electrode 537.

The passivation stack 509 is a dielectric structure that may include various layers, for example, a lower etch stop layer 551, a lower thermally conductive dielectric layer 547, an oxide layer 241, an upper etch stop layer 539, and a barrier layer 535. The lower etch stop layer 551 and the upper etch stop layer 539 are optional and each may be a material such as silicon nitride (SiN), silicon carbide (SiC), silicon carbonitride (SiCN), silicon oxycarbide (SIOC), silicon oxycarbonitiride (SiOCN), a combination thereof, or the like. The lower thermally conductive dielectric layer 547 is also optional. The lower thermally conductive dielectric layer 547 may be a high thermal conductivity dielectric or an extremely high thermal conductivity dielectric.

The oxide layer 241 is a dielectric that provides electrical insulation between the N-type vias 225 and the P-type vias 221 of the TEC 463 and between the chip 500 and an external environment. In some embodiments, the oxide layer 241 is silicon dioxide (SiO₂). In some embodiments, the oxide layer 241 is a low-k dielectric such as may be used as the interlevel dielectric 557 in the metal interconnect structure 125. A low-K dielectric may be, for example, an organosilicate glasses (OSG) such as carbon-doped silicon dioxide, a fluorinated silica glass (FSG), a porous silicate glass, or the like.

In some embodiments, the barrier layer 535 is a high thermal conductivity dielectric. In some embodiments, the barrier layer 535 silicon nitride (Si₃N₄) or the like. Silicon nitride (Si₃N₄) provides superior moisture resistance and has greater mechanical strength than silicon dioxide (SiO₂). If the upper etch stop layer 539 is provided, it has a distinct composition from the barrier layer 535. In some embodiments, the barrier layer 535 is an extremely high thermal conductivity dielectric. The barrier layer 535, and also the lower thermally conductive dielectric layer 547 if included, may extend over a greater area than the TEC 463.

In some embodiments, the passivation stack 509 has a thickness in the range from about 0.5 μm to about 3 μm. In some embodiments, the passivation stack 509 has a thickness in the range from about 1.9 μm to about 2.2 μm. In some embodiments, the etch stop layer 551 has a thickness in the range from about 5 nm to about 50 nm. In some embodiments, the barrier layer 535 has a thickness of at least about 0.2 μm. The barrier layer 535 is much thicker than any etch stop layer in the metal interconnect structure 125.

The height H₁ of the N-type vias 225 and the P-type vias 221 in the TEC 463 and other TECs according to the present disclosure is a design parameter that may be adjusted to improve performance. In some embodiments, the height H₁ is at least about 0.3 μm. In some embodiments, the height H₁ is at least about 1 μm. In some embodiments, the thickness of the oxide layer 241 is equal to the height H₂ of the TEC 463. The height H₂ of the TEC 463 equals the height H₁ plus the thicknesses of the first wiring layer 229 and the second wiring layer 217. In some embodiments, the oxide layer 241 is made thicker that the height H₂ so as to provide greater electrical insulation. In some embodiments, the TEC 463 is entirely within the passivation stack 509 so that the height of the TEC 463 is limited to the thickness of the passivation stack 509. In some embodiments the TEC 463 extends downward into the metal interconnect structure 125. Extending the TEC 463 downward into the metal interconnect structure 125 allows the height H₁ to be made greater than the thickness of the passivation stack 509.

The width W₁ of the N-type vias 225, the width W₂ of the P-type vias 221, and the pitch P₁ of the N-type vias 225 and the P-type vias 221 are also design parameters that may be adjusted to improve performance. In some embodiments, the width W₁ and or the width W₂ is in the range from about 1 μm to about 100 μm. In some embodiments, the width W₁ and or the width W₂ is in the range from about 5 μm to about 50 μm. In some embodiments, the pitch P₁ and or the width W₂ is in the range from about 0.1 μm to about 10 μm.

The first contact pad 517 and the second contact pad 525 are in a bonding layer 513 above the passivation stack 509. A dielectric 521 of the bonding layer 513 surrounds and isolates the first contact pad 517 and the second contact pad 525. In some embodiments, the dielectric 521 is a high thermal conductivity dielectric. In some embodiments, the dielectric 521 is an extremely high thermal conductivity dielectric.

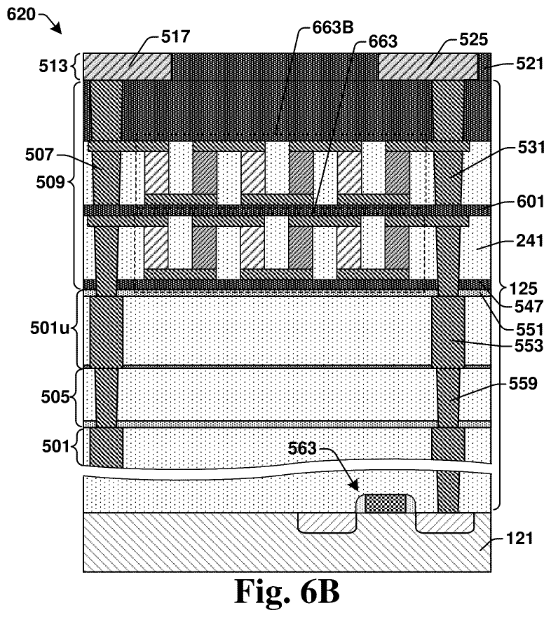

FIG. 6A illustrates a cross-sectional view of a chip 600, which is another chip that may correspond to the first chip 135 in the 3D-IC device 401 of FIG. 4. The chip 600 may be like the chip 500 of FIG. 5 except that the chip 600 has the TEC 663 in place of the TEC 463. The TEC 663 is like the TEC 463 of FIG. 5 except that in the TEC 663 the first electrode 510 is laterally extended so that the first via 507 passes through and contacts the first electrode 510. Likewise, the second electrode 537 is laterally extended so that the second via 531 passes through and contacts the second electrode 537. This allows the third via 511 (see FIG. 5), the fourth via 527, and upper etch stop layer 539 to be omitted. The chip 600 may be easier to manufacture than the chip 500 of FIG. 5.

FIG. 6B illustrates a cross-sectional view of a chip 620, which is another chip that may correspond to the first chip 135 in the 3D-IC device 401 of FIG. 4. The chip 620 is like the chip 500 of FIG. 5 except that the chip 620 include a second TEC 663B vertically stacked with the TEC 663. Any of the embodiments of the present disclosure may be modified to include vertically stacked TECs. Vertically stacking TECs may allow the generation of greater temperature differentials between the hot side and the cold side. A high thermal conductivity dielectric layer 601 may be provided between adjacent TEC's in the stack. In some embodiments and extremely high thermal conductivity dielectric is disposed between vertically stacked TECs.

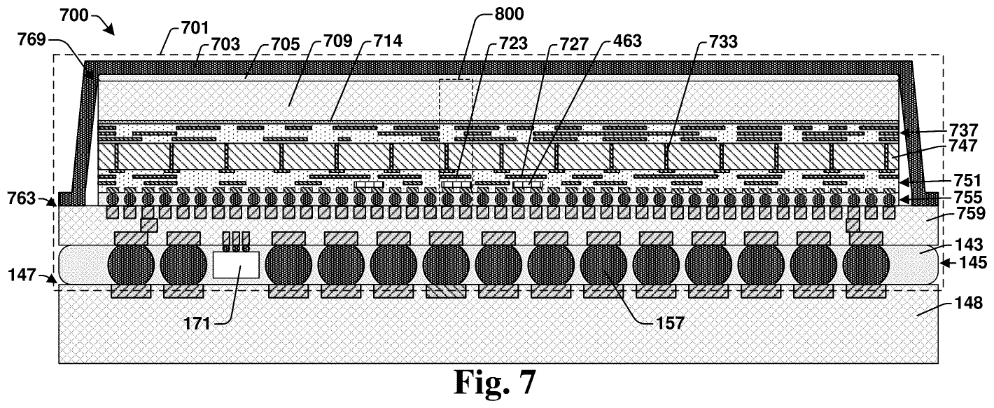

FIG. 7 illustrates an apparatus 700 that includes an IC device 701 in accordance with another embodiment. The IC device 701 is attached to the printed circuit board 147. The IC device 701 has a plurality of device layers including a routing layer 763 and a chip 769. The chip 769 comprises a semiconductor substrate 747, a carrier substrate 709, a front side metal interconnect structure 737 between the semiconductor substrate 747 and the carrier substrate 709, and a back side metal interconnect structure 751 on an opposite side of the semiconductor substrate 747. The routing layer 763 includes a dielectric substrate 759. A C4 connection layer 755 couples the chip 769 to the routing layer 763. The solder connection layer 145 couples the routing layer 763 to the printed circuit board 147.

A V_{SS} rail 723 and a V_{DD} rail 727 are disposed in the back side metal interconnect structure 751. One or more TECs 463 are disposed in the back side metal interconnect structure 751 and are positioned to facilitate heat transfer from hot spots that may be associated with the V_{SS} rail 723 or the V_{DD} rail 727 or devices powered by the V_{SS} rail 723 or the V_{DD} rail 727 to the printed circuit board 147. A lid 703 covering the chip 769 may be provided to dissipate heat upward from the chip 769. A thermal interface material 705 may be used to increase heat transfer from the chip 769 to the lid 703. TECs 463 are disposed in the back side metal interconnect structure 751 and are configured to draw heat in the opposite direction from the lid 703.

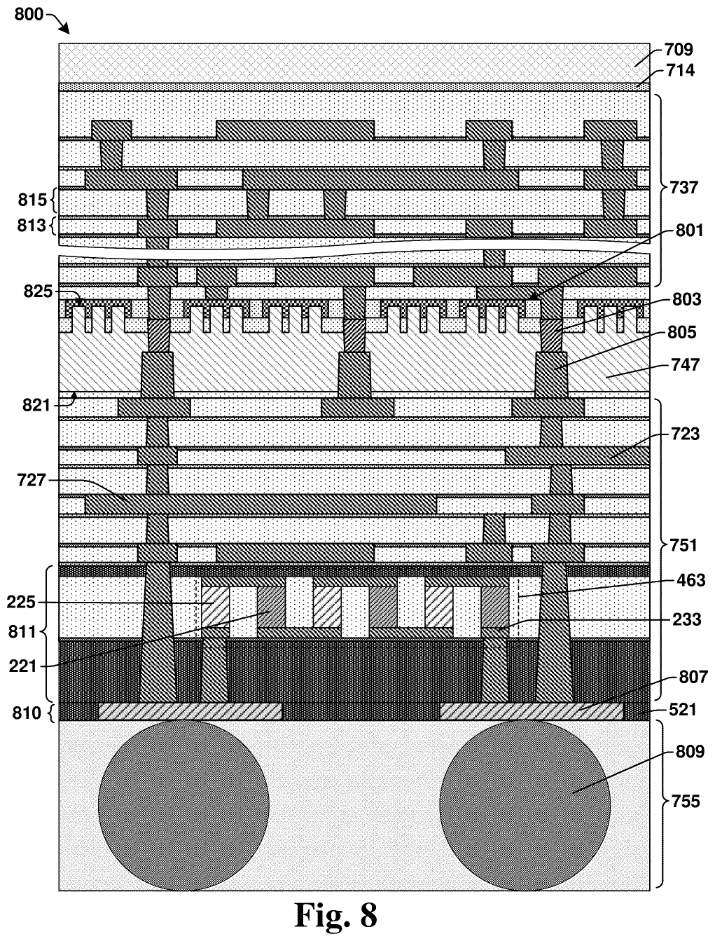

FIG. 8 illustrates a cross-sectional view of a chip 800 that may correspond to the chip 769 of FIG. 7. The chip 800 includes the semiconductor substrate 747, the carrier substrate 709, the front side metal interconnect structure 737, and the back side metal interconnect structure 751. Semiconductors devices such as FinFETs 801 may be disposed on a front side 825 of the semiconductor substrate 747. The V_{SS} rail 723 and the V_{DD} rail 727 are disposed in the back side metal interconnect structure 751, which is on a back side 821 of the semiconductor substrate 747. Buried rails 803 are disposed proximate the front side 825. The FinFETs 801 are powered by the buried rails 803. The buried rails 803 are in turn powered by the V_{SS} rail 723 and the V_{DD} rail 727. The buried rails 803 are connected to the V_{SS} rail 723 and the V_{DD} rail 727 by through substrate vias 805.

The TEC 463 is disposed in the passivation stack 811, which is the outermost portion of the back side metal interconnect structure 751. The TEC 463 may be coupled to C4 solder bumps 809 through contact pads 807. The structure, surrounding structure, and connectivity of the TEC 463 may be as in the chip 500 of FIG. 5 or in the manner of the TEC 663 in the chip 600 of FIG. 6.

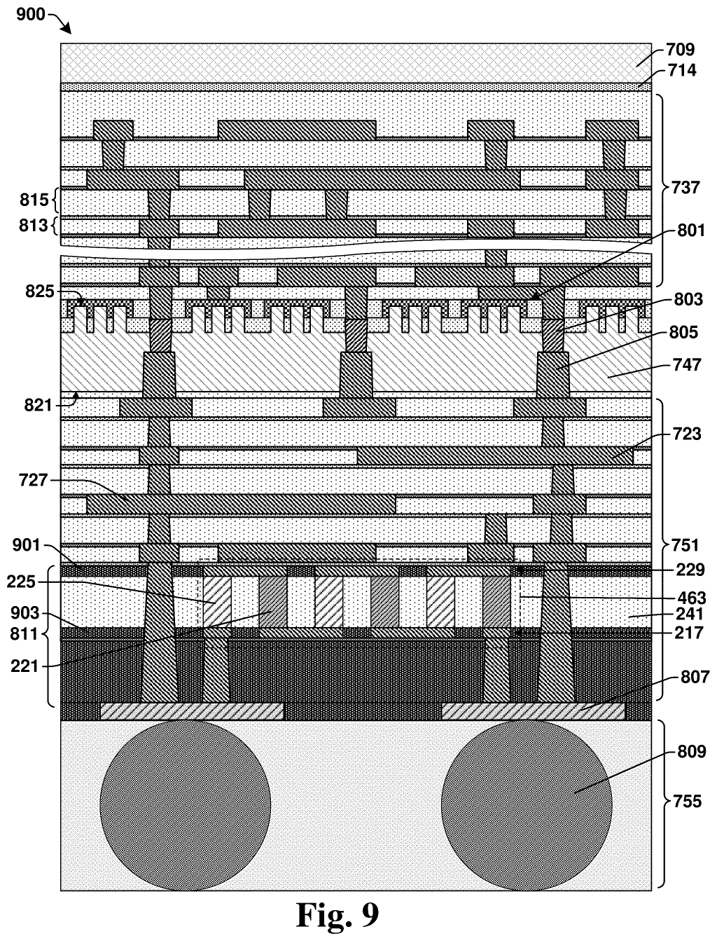

FIG. 9 illustrates a cross-sectional view of a chip 900 that is another chip that may correspond to the chip 769 of FIG. 7. The chip 900 is like the chip 800 of FIG. 8 except that in the chip 900 the dielectric 901 of the first wiring layer 229 and the dielectric 903 of the second wiring layer 217 have a distinct composition from the oxide layer 241. In some embodiments, one or both of the dielectric 901 and the dielectric 903 are high thermal conductivity dielectrics. In some embodiments, one or both of the dielectric 901 and the dielectric 903 are extremely high thermal conductivity dielectrics.

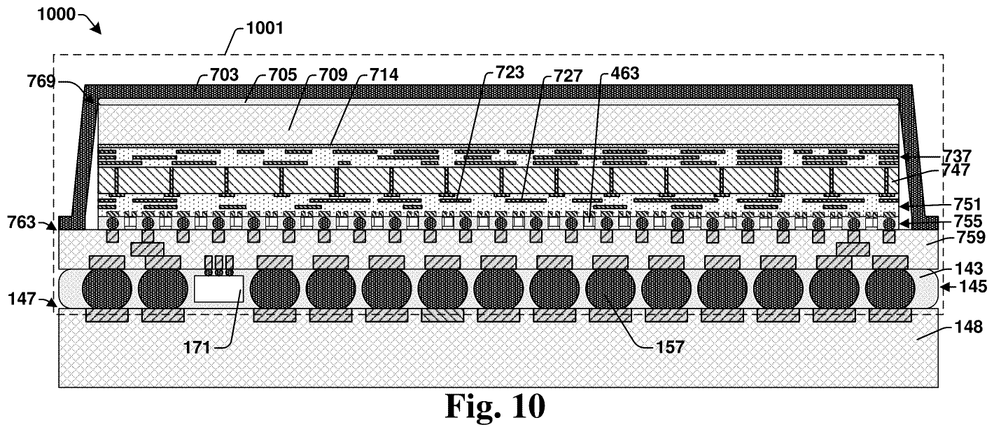

FIG. 10 illustrates an apparatus 1000 that includes an IC device 1001 in accordance with another embodiment. The IC device 1001 is like the IC device 701 of FIG. 7 except that instead of having the TECs 463 disposed in the back side metal interconnect structure 751, the IC device 1001 has the TECs 463 in the C4 connection layer 755. Alternatively, there may be TEC 463 in both those location and also in the solder connection layer 145.

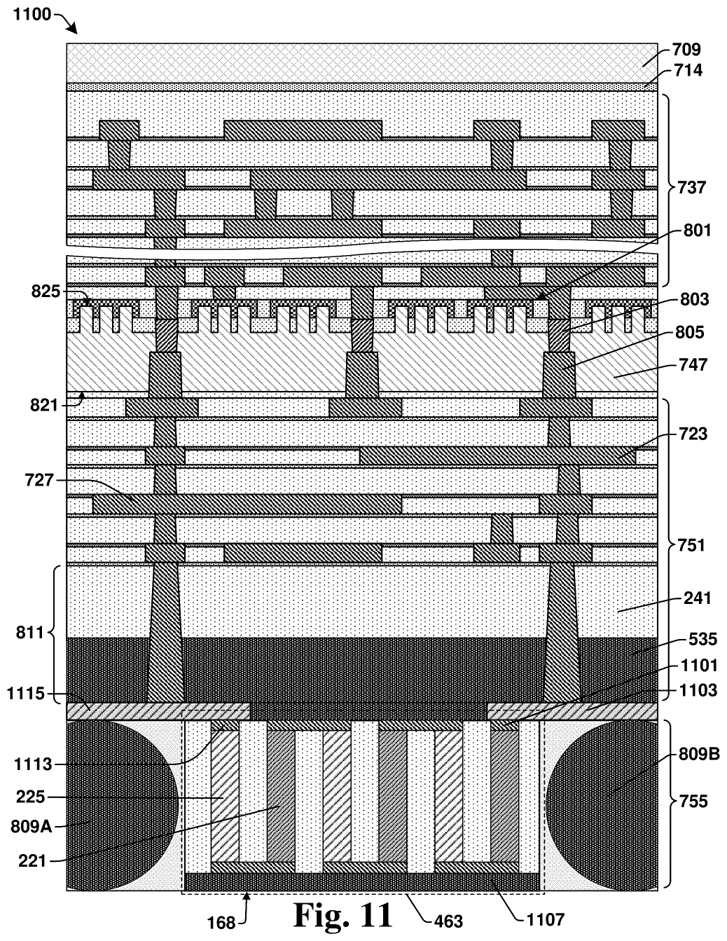

FIG. 11 illustrates a cross-sectional view of a chip 1100 that may correspond to the chip 769 in the IC device 1001 of FIG. 10. As shown in FIG. 11, a first electrode 1113 and a second electrode 1103 of the TEC 463 may be disposed between a first C4 solder bump 809A and a second C4 solder bump 809B in the C4 connection layer 755. In the chip 1100, the TEC 463 has a high thermal conductivity dielectric 1107 on the hot side 168, which is opposite the back side metal interconnect structure 751. The first C4 solder bump 809A and the first electrode 1113 may both abut a first contact pad 1115 and the second C4 solder bump 809B and the second electrode 1101 may both abut a second electrode 1103, whereby the TEC 463 may be powered through the first C4 solder bump 809A and the second C4 solder bump 809B.

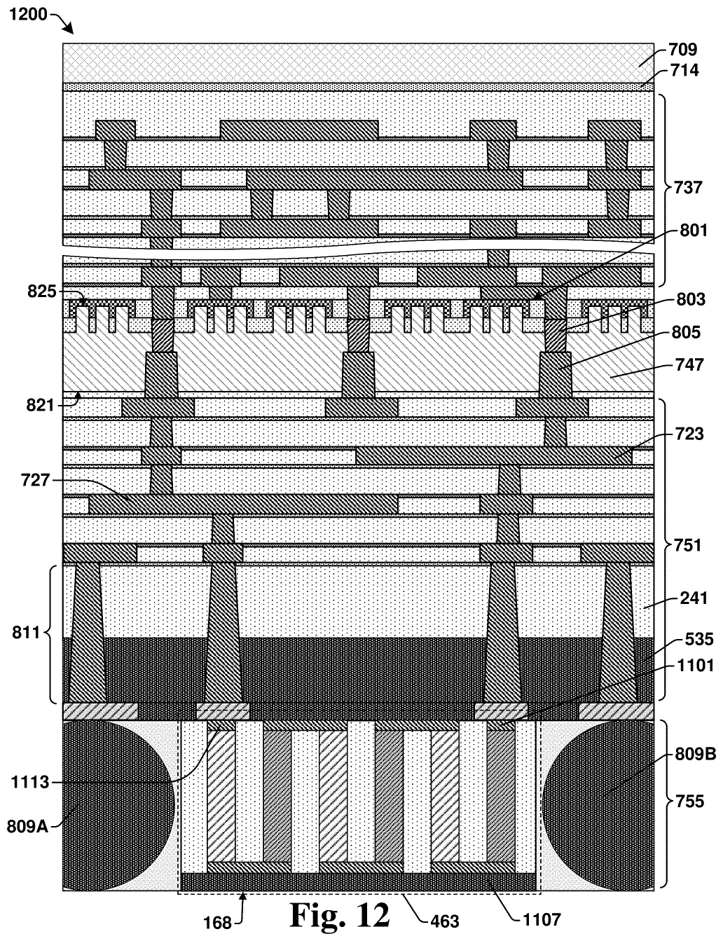

FIG. 12 illustrates a cross-sectional view of a chip 1200, which is another chip that may correspond to the chip 769 in the IC device 1000 of FIG. 10. In the chip 1200, the TEC 463 draws power from the V_{SS} rail 723 and the V_{DD} rail 727 in the back side metal interconnect structure 751.

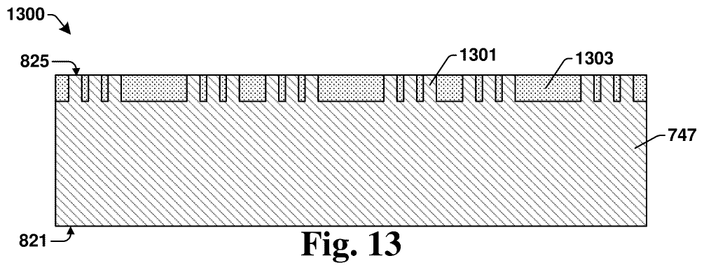

FIGS. 13-42 provide a series of cross-sectional views 1300-4200 that illustrate an integrated circuit device according to the present disclosure at various stages of manufacture according to a process in accordance with some embodiments. Although FIGS. 13-42 are described in relation to a series of acts, it will be appreciated that the order of the acts may in some cases be altered and that this series of acts are applicable to structures other than the ones illustrated. In some embodiments, some of these acts may be omitted in whole or in part. Furthermore, FIGS. 13-42 are described in relation to a series of acts, it will be appreciated that the structures shown in FIGS. 13-42 are not limited to a method of manufacture but rather may stand alone as structures separate from the method.

As shown by the cross-sectional view 1300 of FIG. 13, the process may begin with formation of semiconductor fins 1301 on the front side 825 of the semiconductor substrate 747. A dielectric 1303 fills gaps between the semiconductor fins 1301. The semiconductor substrate 747 may be a bulk semiconductor substrate or a semiconductor on insulator (SOI) substrate. At least an upper portion of the semiconductor substrate 747 is a semiconductor. The semiconductor may be silicon (Si), a group III-V semiconductor (e.g., GaAs) or some other binary semiconductor, a tertiary semiconductor (e.g., AlGaAs), a higher order semiconductor, the like, or any other suitable semiconductor. In some embodiments, the bulk semiconductor is silicon (Si) or the like. The semiconductor fins 1301 may be a different type of semiconductor epitaxially grown on the front side 825. The dielectric 1303 may be silicon dioxide (SiO₂), the like, or some other suitable dielectric.

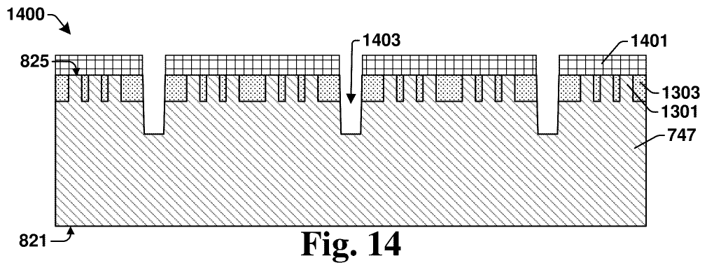

As shown by the cross-sectional view 1400 of FIG. 14, the process may continue with formation of a mask 1401 and etching to form trenches 1403. The trenches 1403 pass through the dielectric 1303 and extend into the semiconductor substrate 747 below the semiconductor fins 1301. The mask 1401 and other masks used in processes of this disclosure may be or comprise a photoresist, a hard mask, a combination thereof, or the like. The mask 1401 and other masks used in this process may be patterned by photolithography, ion beam lithography, the like, or some other suitable process. An etch process may be a dry etch such as a plasma etch, the like, or some other suitable etch process. After the etch process, the mask 1401 may be stripped.

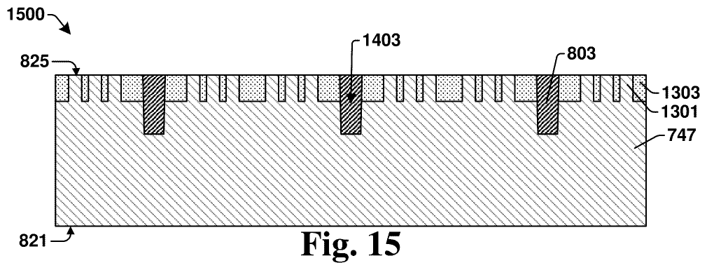

As shown by the cross-sectional view 1500 of FIG. 15, a metal may be deposited so as to fill the trenches 1403 and form buried rails 803. The buried rails 803 may be isolated from the semiconductor substrate by a dielectric liner (not shown). The metal is selected for its ability to withstand front-end-of-line (FEOL) processing and for low susceptibility to electromigration. The metal may be, for example, ruthenium (Ru), tungsten (W), molybdenum (Mo), a combination or alloy thereof, or the like. The metal may be deposited by physical vapor deposition (PVD), chemical vapor deposition (CVD), atomic layer deposition (ALD), electroplating, electroless plating, the like, or any other suitable process. Excess metal may be removed by a planarization process. The planarization process may be, for example, chemical mechanical polishing (CMP), the like, or any other suitable process.

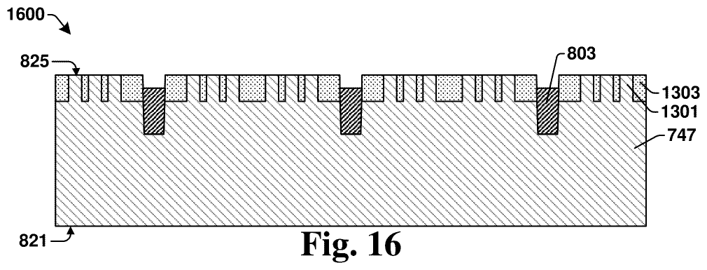

As shown by the cross-sectional view 1600 of FIG. 16, an etch process is carried out to recess the buried rails 803. This etch process may reduce or eliminate the need for a planarization process to remove excess metal. The etch process may be a dry etch process or a wet etch process.

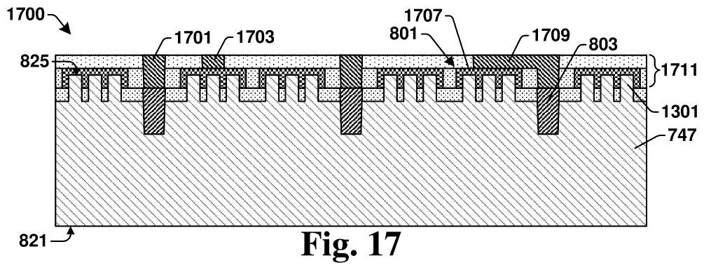

As shown by the cross-sectional view 1700 of FIG. 17, FEOL processing may be completed after formation of the buried rails 803. FEOL processing may form the finFETs 801 which comprise gate electrodes 1707 over the semiconductor fins 1301. FEOL processing may also, or in the alternative, form other semiconductor devices on the front side 825. FEOL processing includes the formation of a transistor-level metal interconnect 1711. The transistor-level metal interconnect 1711 includes vias 1701 that contact the buried rails 803, vias 1703 that contact the gate electrodes 1707, and wires 1709. Some of the wires 1709 may couple buried rails 803 to gate electrodes 1707. Other wires 1709 (not shown) may couple source/drain regions (not shown) of the finFETs 801 to the buried rails 803. Subsequent processing will provide TSVs 733 (see FIG. 7) through which the buried rails 803 are connected to a power source. In this manner, the buried rails 803 allow the finFETs 801 to be powered from the back side 821 so that heat generation by IR losses on the front side 825 is reduced.

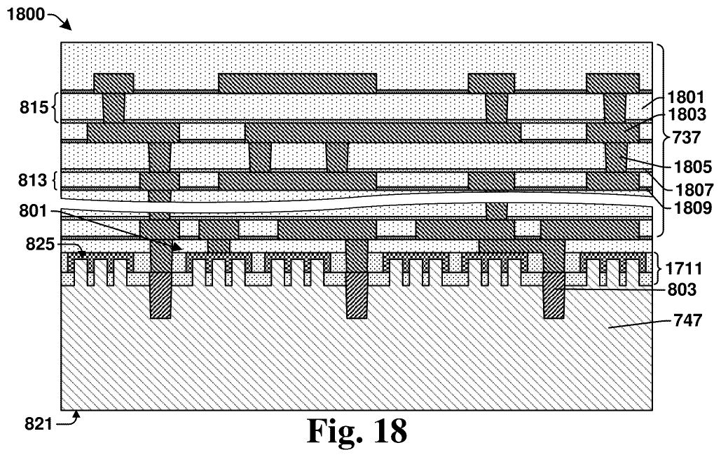

As shown by the cross-sectional view 1800 of FIG. 18, back-end-of-line (BEOL) processing may be carried out to form the front side metal interconnect structure 737 over the transistor-level metal interconnect 1711. The front side metal interconnect structure 737 includes a plurality of metallization layers 813 and a plurality of via layers 815. The via layers 815 are disposed between adjacent pair of the metallization layers 813. The metallization layers 813 contain wires 1803 and the via layers 815 contain vias 1805. An interlevel dielectric 1801 fills areas between the wires 1803 and the vias 1805. Via etch stop layers 1807 may be formed at the base of each via layer 815 and wire etch stop layers 1809 may be formed at the base of each metallization layer 813. The front side metal interconnect structure 737 may be formed by damascene processes, dual damascene processes, or any other suitable type of processing.

The wires 1803 and the vias 1805 comprises a conductive material such as a metal. The metal may be, for example, copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, or the like. The interlevel dielectric 1801 may be silicon dioxide (SiO₂) or the like, a low-K dielectric, or an extremely low-K dielectric. A low-K dielectrics has a lower dielectric constant than silicon dioxide (SiO₂). Examples of low-K dielectrics include organosilicate glasses (OSG) such as carbon-doped silicon dioxide, fluorine-doped silicon dioxide (otherwise referred to as fluorinated silica glass (FSG), organic polymer low low-K dielectrics, and porous silicate glass. An extremely low-K dielectric is a material having a dielectric constant of about 2.1 or less. An extremely low-K dielectric material is generally a low-K dielectric material formed into a porous structure. Porosity reduces the effective dielectric constant. The via etch stop layers 1807 and the wire etch stop layers 1809 may have the same or differing compositions and each may include one or more layers of silicon nitride (SiN), silicon carbide (SiC), silicon carbonitride (SiCN), silicon oxycarbide (SIOC), silicon oxycarbonitiride (SiOCN), combinations thereof, or the like.

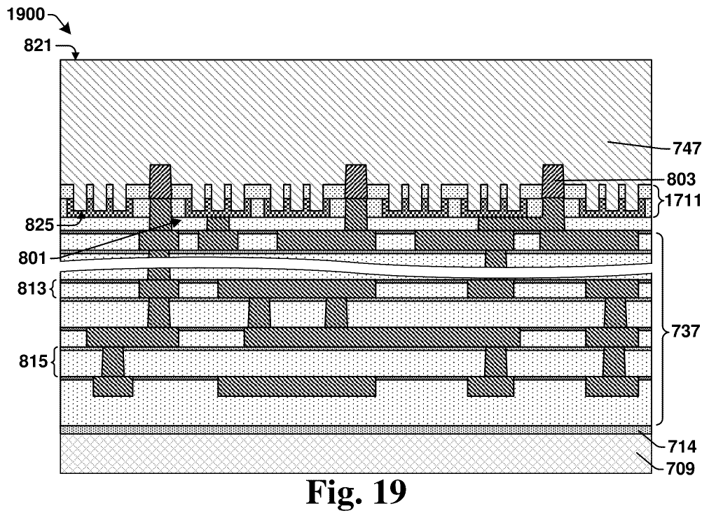

As shown by the cross-sectional view 1900 of FIG. 19, the partially manufactured device shown by the cross-sectional view 1800 of FIG. 18 may be bound to the carrier substrate 709 through a bonding layer 714. The carrier substrate 709 may be a dielectric substrate or any other suitable type of substrate. The bonding layer 714 may be any suitable type of bonding material.

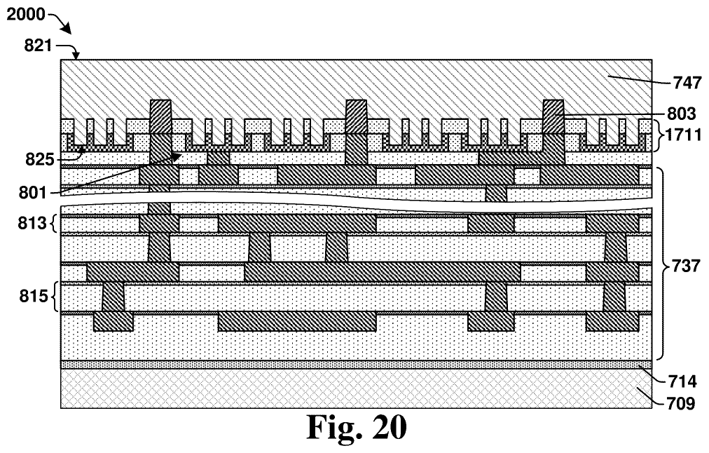

As shown by the cross-sectional view 2000 of FIG. 20, after bonding to the carrier substrate 709 the semiconductor substrate 747 may be thinned from the back side 821. In some embodiments, the semiconductor substrate 747 is thinned to about 50 microns or less. In some embodiments, the semiconductor substrate 747 is thinned to about 5 microns or less. In some embodiments, the semiconductor substrate 747 is thinned to about 1 micron or less. The thinner the semiconductor substrate 747, the lower the heat generation rate. Thinning may include grinding, polishing, CMP, the like, or any other suitable process.

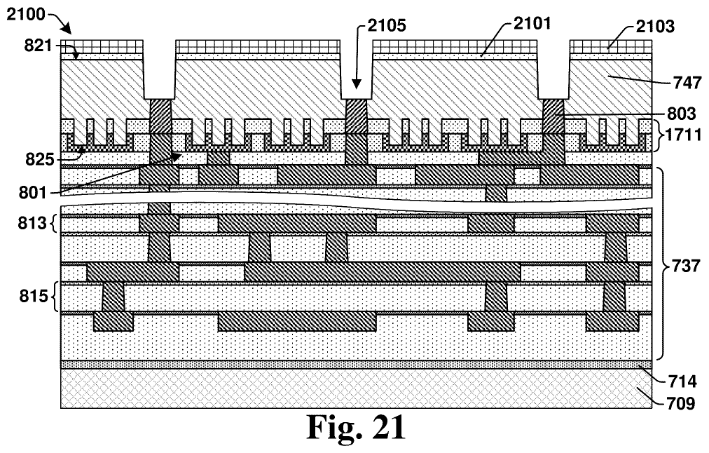

As shown by the cross-sectional view 2100 of FIG. 21 a dielectric layer 2101 and a mask 2103 are formed on the back side 821. The mask 2103 is used to etch holes 2105 through which the buried rails 803 are exposed.

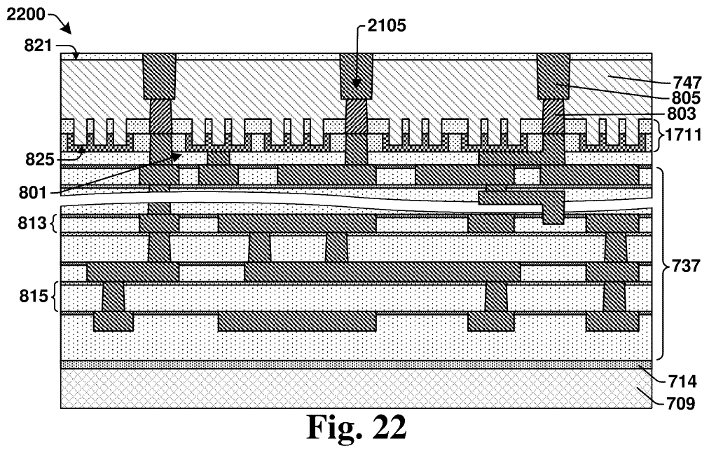

As shown by the cross-sectional view 2200 of FIG. 22, TSVs 733 are formed in the holes 2105. Forming the TSVs 733 may include depositing a dielectric liner (not shown) etching to break through the liner at the bottoms of the holes 2105, depositing a conductive material so as to fill the holes 2105, and planarization to remove excess conductor. In some embodiments, the conductive material is a metal. Examples of metals that may be suitable include copper (Cu), tungsten (W), aluminum (Al), combinations thereof, and the like. The metal may be deposited by PVD, CVD, ALD, electroplating, electroless plating, the like, or any other suitable process.

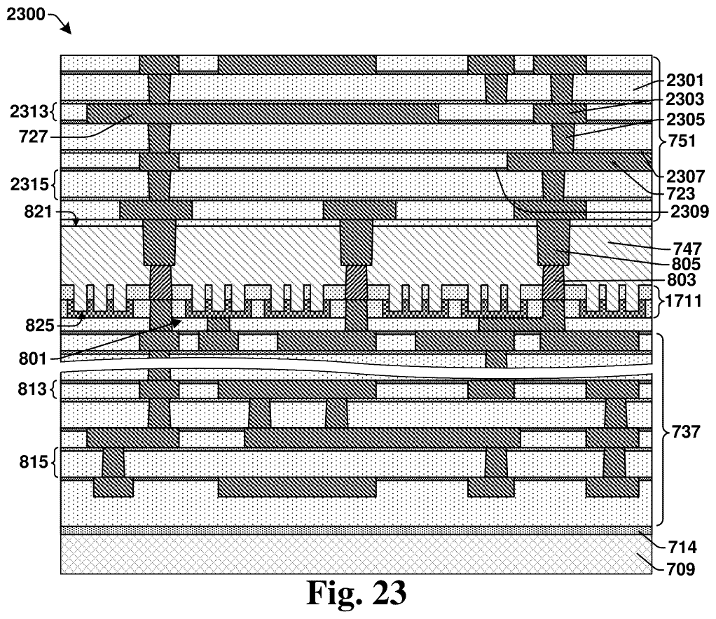

As shown by the cross-sectional view 2300 of FIG. 23, the back side metal interconnect structure 751 is formed over the back side 821. The back side metal interconnect structure 751 include a plurality of metallization layers 2313 and a plurality of via layers 2315. The metallization layers 2313 contain wires 2303 among which are the V_{SS} rail 723 and the V_{DD} rail 727. The via layers 2315 contain vias 2305. An interlevel dielectric 2301 fills areas between the wires 2303 and the vias 2305. Via etch stop layers 2307 may be formed at the base of each via layer 2315 and wire etch stop layers 2309 may be formed at the base of each metallization layer 2313. The back side metal interconnect structure 751 may be formed using the same types of methods and materials as the front side metal interconnect structure 737.

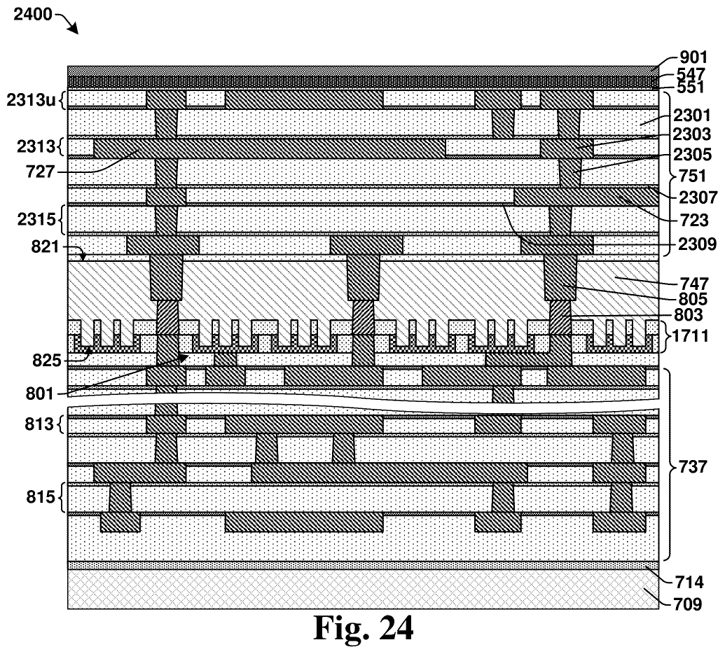

As shown by the cross-sectional view 2400 of FIG. 24, several layers may be formed over the uppermost metallization layer 2313u of the back side metal interconnect structure 751. The several layers may include the lower etch stop layer 551, the lower thermally conductive dielectric layer 547, and the dielectric 901. Each of the lower etch stop layer 551 and the lower thermally conductive dielectric layer 547 is optional. The lower thermally conductive dielectric layer 547 may be a high thermal conductivity dielectric layer or an extremely high thermal conductivity dielectric layer. The dielectric 901 may be a conventional dielectric, such as a silicon dioxide (SiO₂) or the like, a high thermal conductivity dielectric layer or an extremely high thermal conductivity dielectric layer. Each of these layers may be deposited by PVD, CVD, ALD, the like, or any other suitable process.

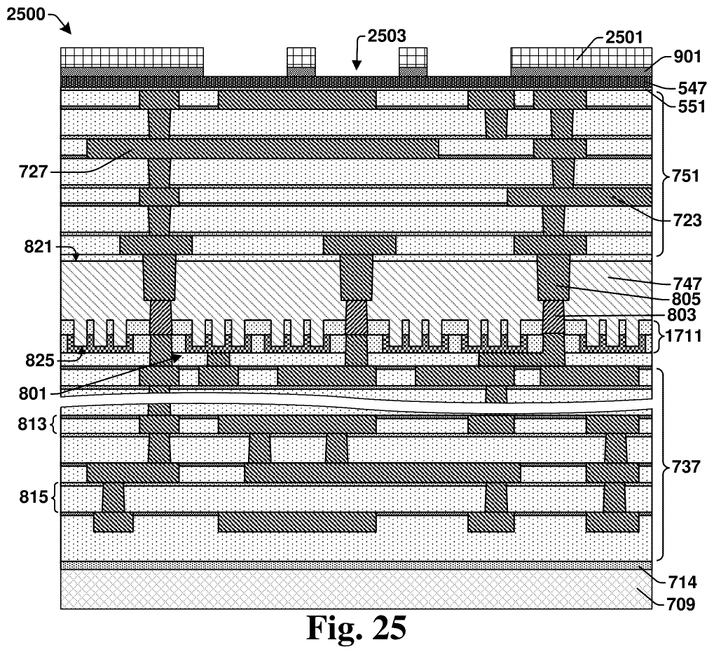

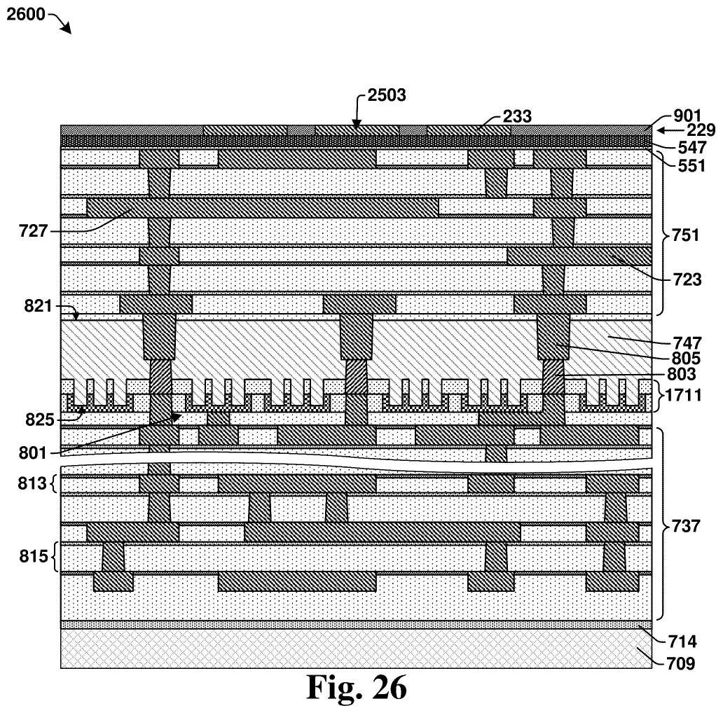

As shown by the cross-sectional view 2500 of FIG. 25, a mask 2501 may be formed and used to etch trenches 2503 in the dielectric 901. After etching, the mask 2501 may be stripped. As shown by the cross-sectional view 2600 of FIG. 26, the trenches 2503 may then be filled to form the first wires 233. The first wires 233 may be a metal or some other conductive material. The metal may be, for example, copper (Cu), tungsten (W), ruthenium (Ru), palladium (Pd), platinum (Pt), cobalt (Co), nickel (Ni), zirconium (Zi), titanium (Ti), tantalum (Ta), aluminum (Al), conductive carbides, oxides, alloys of these metals, or the like. The metal may be deposited by PVD, CVD, ALD, electroplating, electroless plating, the like, or any other suitable process. Excess metal may be removed by a planarization process. The planarization process may be CVD, the like, or any other suitable process. The dielectric 901 and the first wires 233 constitute the first wiring layer 229.

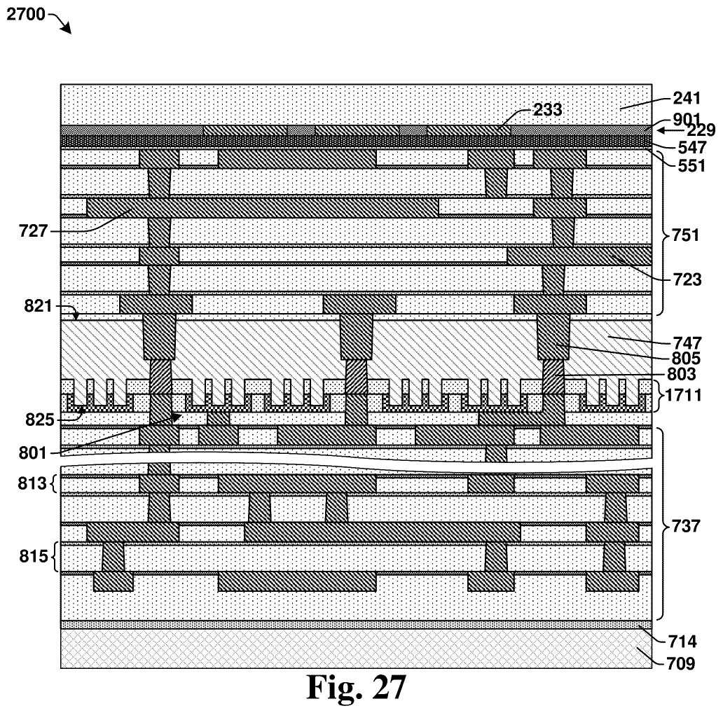

As shown by the cross-sectional view 2700 of FIG. 27, the oxide layer 241 is deposited over the first wiring layer 229. The oxide layer 241 may be silicon dioxide (SiO₂), a low-k dielectric, or an extremely low-k dielectric. The oxide layer 241 may be deposited by CVD, PVD, ALD, the like, or any other suitable process.

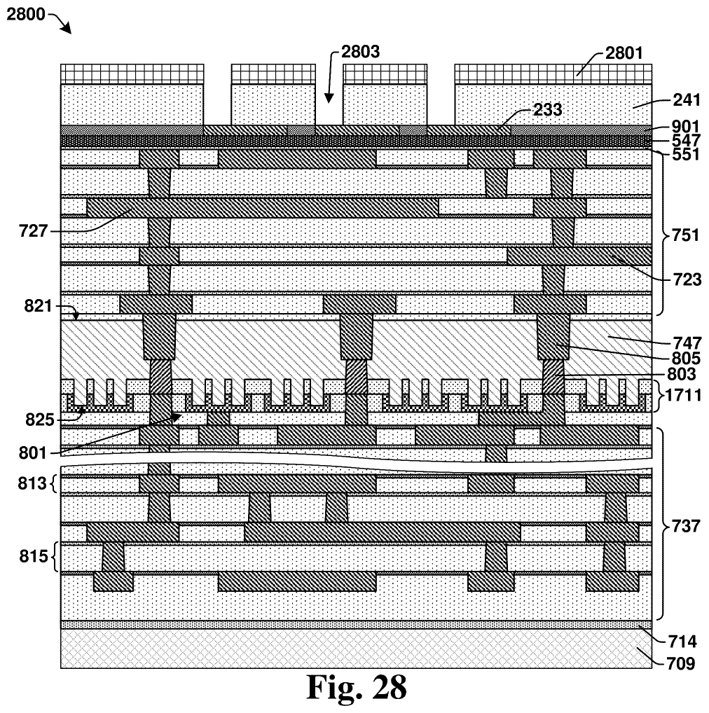

As shown by the cross-sectional view 2800 of FIG. 28, a mask 2801 is formed and used to etch first holes 2803 through the oxide layer 241. The first wires 233 are exposed at the bottoms of the first holes 2803. The etch process may be a dry etch such as a plasma etch, the like, or any other suitable process. After etching, the mask 2801 may be stripped.

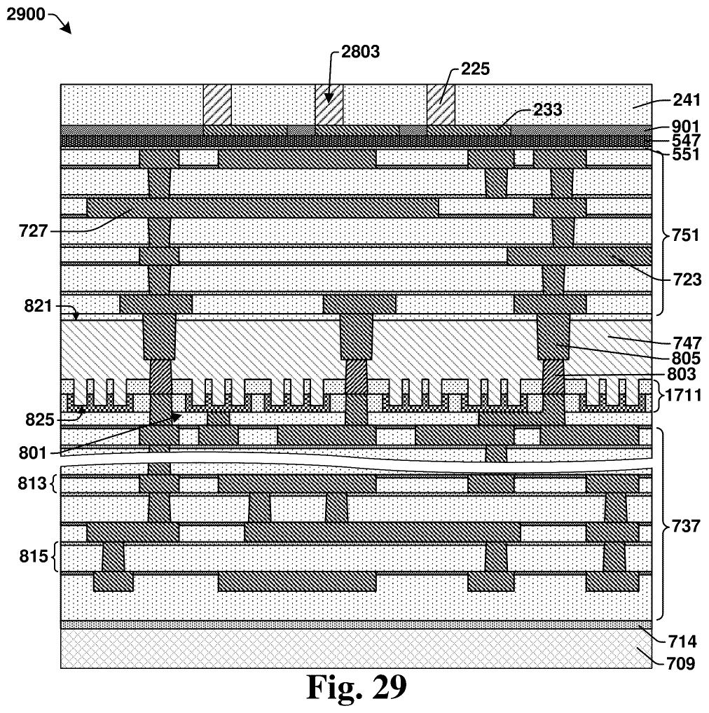

As shown by the cross-sectional view 2900 of FIG. 29, the first holes 2803 are filled with a semiconductor material having a high thermoelectric figure of merit and N-type doping to form the N-type vias 225. A high thermoelectric figure of merit is 1.0 or greater. The greater the thermoelectric figure of merit, the greater the efficiency of the resulting thermoelectric cooler. Examples of semiconductor materials having a high thermoelectric figure include bismuth telluride-based compounds (BiTe—), antimony telluride-based compounds (SbTe—), antimony bismuth telluride-based compounds (Bi_{2-y}Sb_{y}Te—), lead telluride (PbTe), silicon germanium (SiGe), skutterudite compounds, zinc antimonide (Zn₃Sb₃), germanium telluride (GeTe), half-Heusler compounds, the like, and others. Examples of bismuth telluride-based compounds include Bi₂(TeₓSe₁₋ₓ)₃ and the like. Examples of antimony telluride-based compounds include Sb₂(TeₓSe₁₋ₓ)₃ and the like. Examples of antimony bismuth telluride-based compounds include Bi_{2-y}Sb_{y}(TeₓSe₁₋ₓ)₃ and the like. In these formulas, x and y can independently have any values from 0 to 1. Examples of skutterudite compounds include cobalt antimonide (CoSb₃) and the like. Examples of half-Heusler compounds include as hafnium nickel stannide (HfNiSn), zirconium nickel stannide (ZrNiSn), and the like. The N-type dopant may be, for example, phosphorous (P), arsenic (As), antimony (Sb), or the like. The semiconductor material may be deposited by sintering, CVD, PVD, ALD, pulsed laser deposition (PLD), the like, or any other suitable process. In some embodiments, the process is PLD for low temperature compatibility. Excess semiconductor material may be removed by a planarization process such as CMP or the like.

In some embodiments, the semiconductor material includes a nanostructure that increased the thermoelectric figure of merit. Using nanostructures, the thermoelectric figure of merit may be increased to 2.0 or greater. Examples of nanostructures include quantum dots and superlattices. Quantum dots may be nanoparticles of a semiconductor cadmium selenide (CdSe), cadmium telluride (CdTe), lead sulfide (PbS), indium arsenide (InAs), or the like.

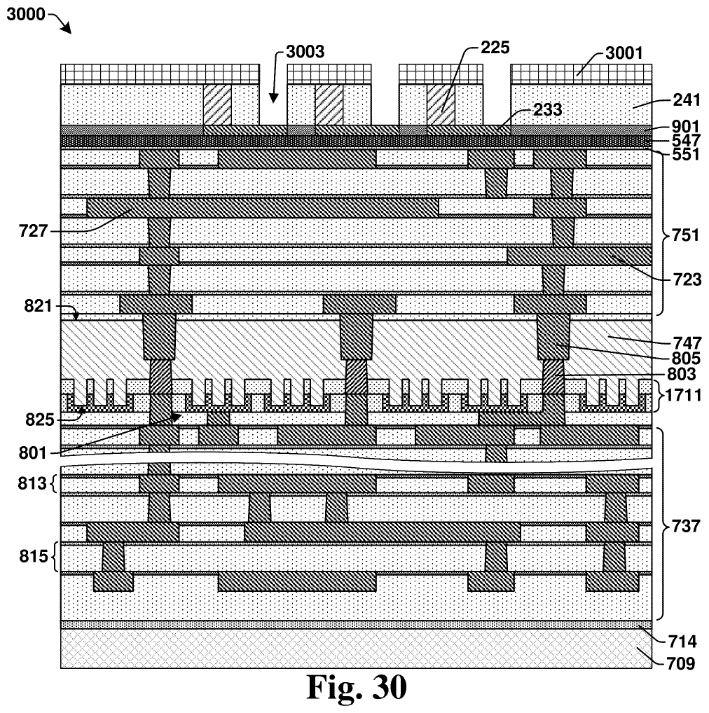

As shown by the cross-sectional view 3000 of FIG. 30, a mask 3001 is formed and used to etch second holes 3003 through the oxide layer 241. The first wires 233 are exposed at the bottoms of the second holes 3003. The etch process may be a dry etch such as a plasma etch, the like, or any other suitable process. After etching, the mask 3001 may be stripped.

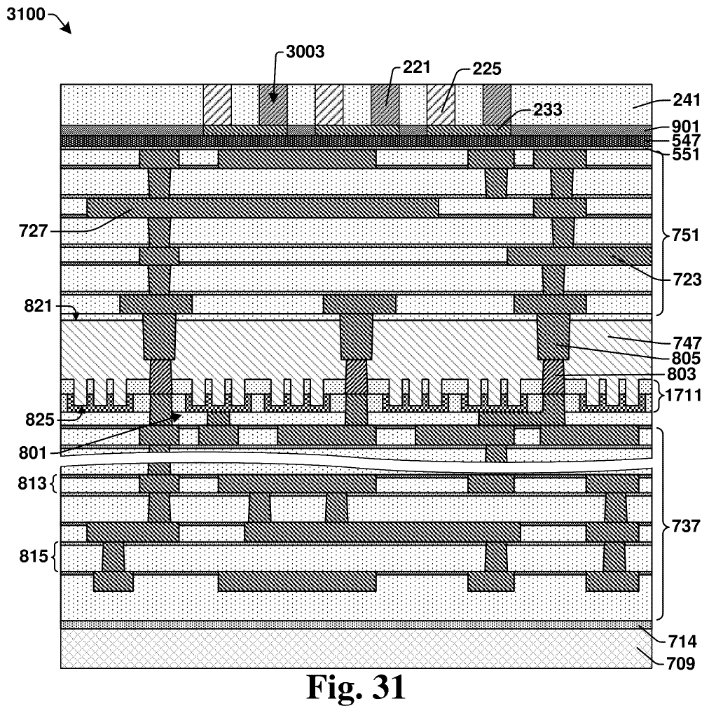

As shown by the cross-sectional view 3100 of FIG. 31, the second holes 3003 are filled with a semiconductor material having a high thermoelectric figure of merit and P-type doping to form the P-type vias 221. The P-type dopant may be, for example, boron (B), aluminum (Al), gallium (Ga), indium (In), or the like. The P-type vias 221 and the N-type vias 225 may be different semiconductor materials in addition to being semiconductors having different doping types.

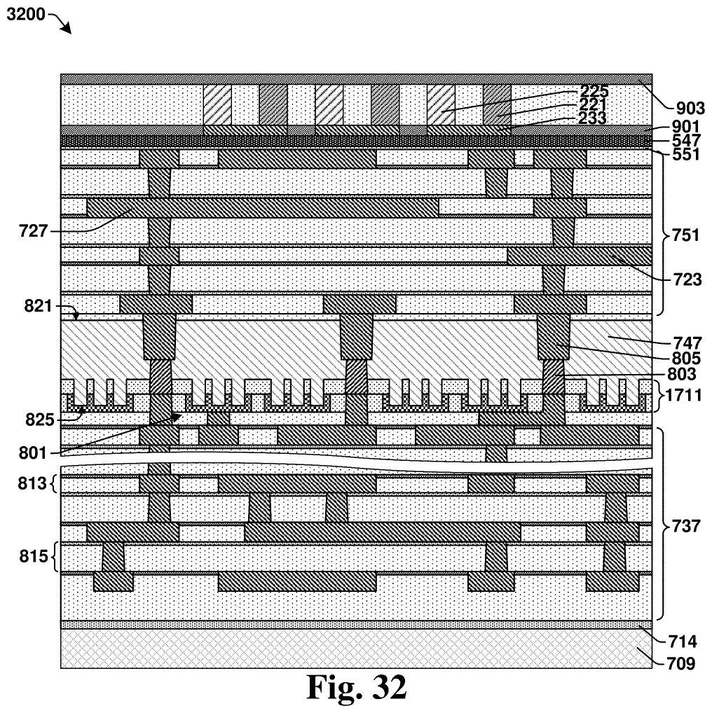

As shown by the cross-sectional view 3200 of FIG. 32, the dielectric 903 may be formed over the P-type vias 221 and the N-type vias 225. The dielectric 903 may be a conventional dielectric, such as a silicon dioxide (SiO₂) or the like, a high thermal conductivity dielectric layer, or an extremely high thermal conductivity dielectric layer and may be deposited by PVD, CVD, ALD, the like, or any other suitable process.

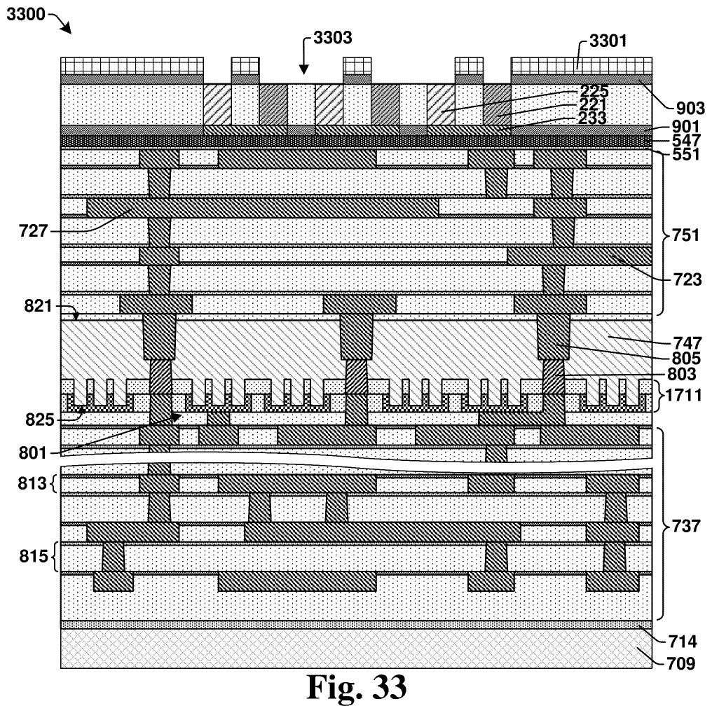

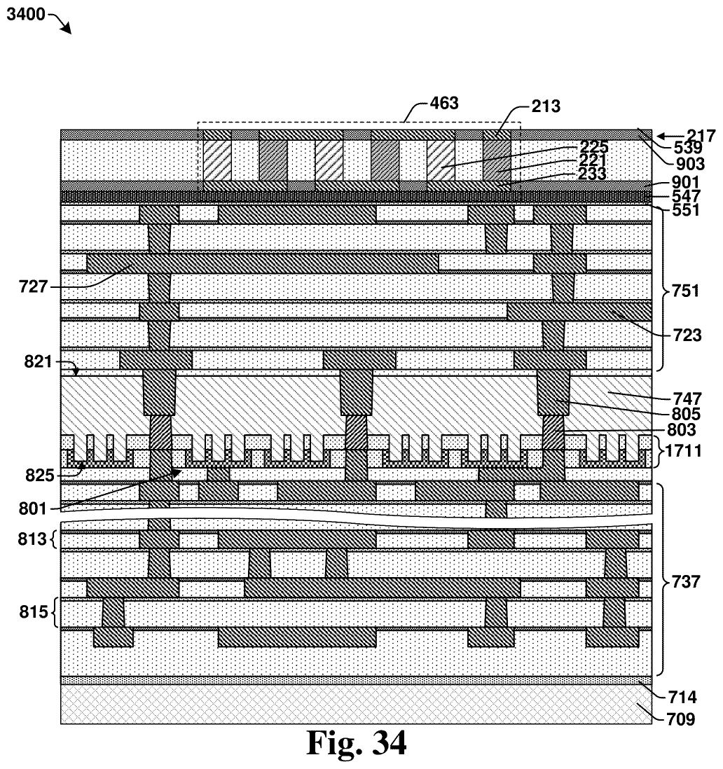

As shown by the cross-sectional view 3300 of FIG. 33, a mask 3301 may be formed and used to etch trenches 3303 in the dielectric 903. After etching the mask 3301 may be stripped. As shown by the cross-sectional view 3400 of FIG. 34, the trenches 3303 may then be filled to form the second wires 213. The compositions and methods of formation for the second wires 213 are like those for the first wires 233. The dielectric 903 and the second wires 213 comprise the second wiring layer 217. Forming the second wiring layer 217 completes the formation of the TEC 463.

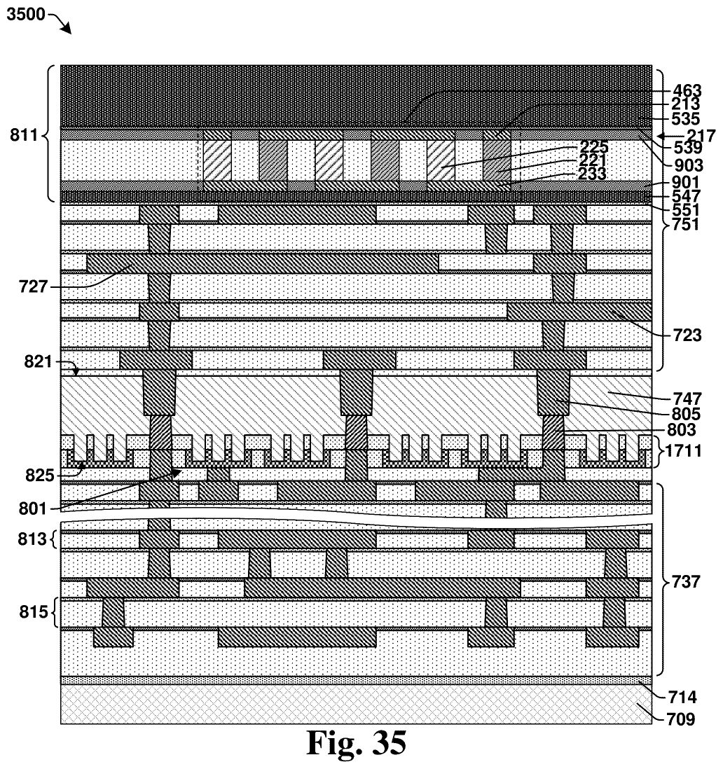

As shown by the cross-sectional view 3500 of FIG. 35, remaining layers of the passivation stack 811 may be deposited over the second wiring layer 217. These may include the upper etch stop layer 539 and the barrier layer 535. Each of these layers may be deposited by PVD, CVD, ALD, the like, or any other suitable process.

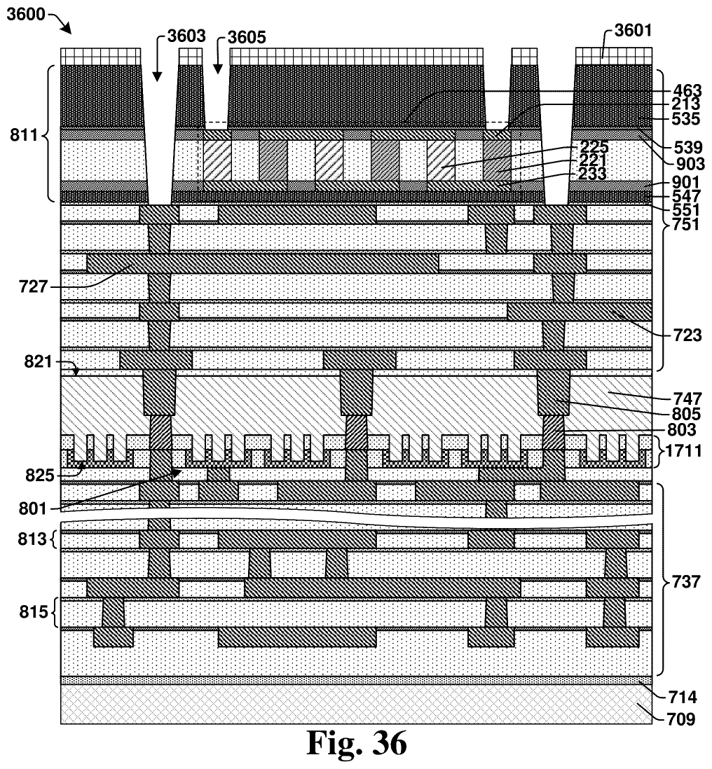

As shown by the cross-sectional view 3600 of FIG. 36, a mask 3601 is formed and used to etch first holes 3603 and second holes 3605. The upper etch stop layer 539 and the lower etch stop layer 551 facilitate these etch processes. The etch may be a dry etch such as a plasma etch or the like. The first holes 3603 may be partially etched before the second holes 3605 or the etching of these holes of differing depths may be accomplished with two separate masks in two separate processes. If the TEC is made like the TEC 663 of FIG. 6, the second holes 3605 need not be formed. After etching, the mask 3601 may be stripped.

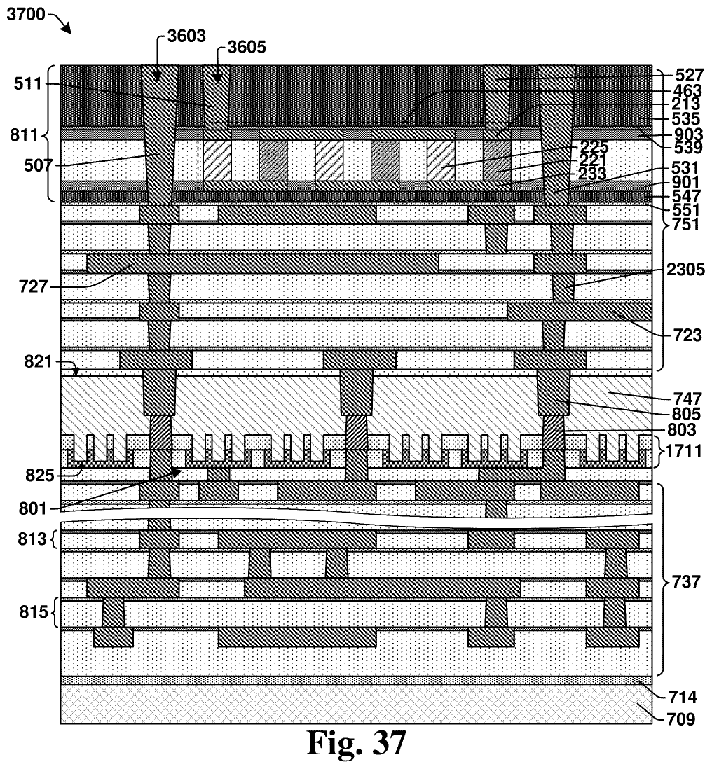

As shown by the cross-sectional view 3700 of FIG. 37, a conductive material may be deposited so as to fill the first holes 3603 and the second holes 3605 and thereby form the first via 507, the second via 531, the third via 511, and the fourth via 527. The compositions and method of deposition for the conductive material may be as described for the vias 2305 of the back side metal interconnect structure 751.

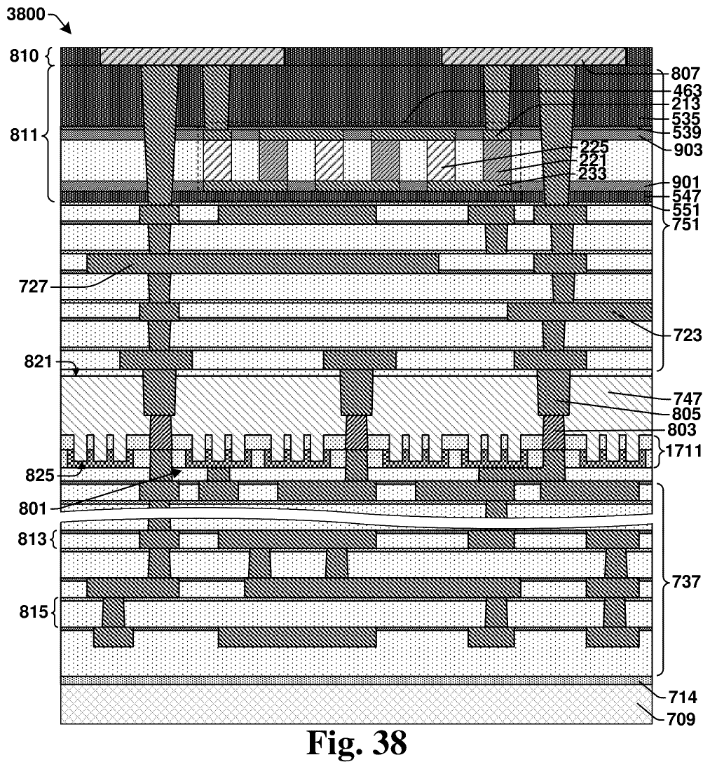

As shown by the cross-sectional view 3800 of FIG. 38, the pad layer 810 may be formed over the passivation stack 811. The pad layer 810 may include the dielectric 521 and the contact pads 807. The contact pads 807 may be formed by a damascene process, the like, or some other suitable process. The contact pads 807 are a metal providing a solderable surface and may be or comprise, for example, copper (Cu), tungsten (W), gold (Au), palladium (Pd), platinum (Pt), titanium (Ti), tantalum (Ta), aluminum (Al), an alloy thereof, or the like.

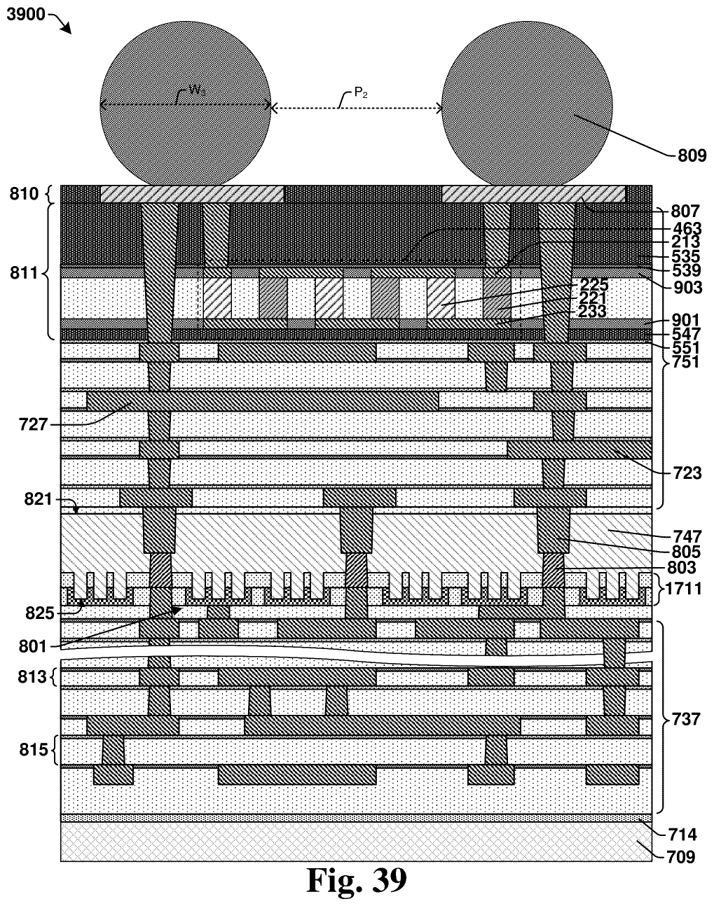

As shown by the cross-sectional view 3900 of FIG. 39, C4 solder bumps 809 may be placed on the contact pads 807. The C4 solder bumps 809 may be an alloy of metals such as lead (Pb), tin (Sn), copper (Cu), silver, (Ag), gold (Au), nickel (Ni), or the like. In some embodiments, the C4 solder bumps 809 are a eutectic alloy. In some embodiments, the C4 solder bumps 809 have a width W₃ in the range from about 10 microns to about 100 microns. In some embodiments, the C4 solder bumps 809 have a pitch P₂ in the range from range from about 10 microns to about 300 microns.

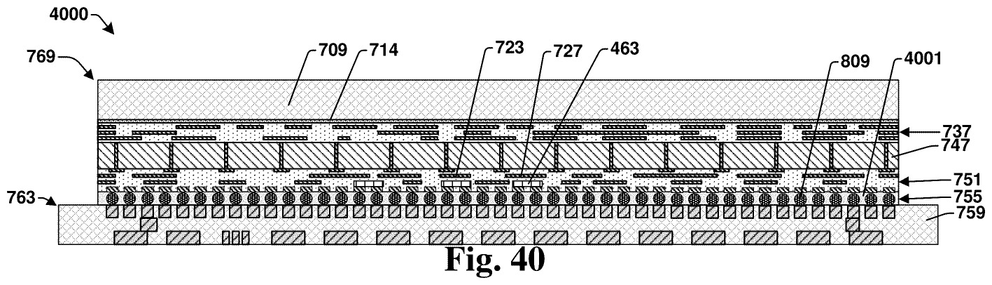

As shown by the cross-sectional view 4000 of FIG. 40, the partially manufactured device shown in the cross-sectional view 3900 of FIG. 39, which includes the semiconductor substrate 747 and the carrier substrate 709, may be connected to the routing layer 763 through the C4 solder bumps 809. A thermal paste 4001 may be applied around the C4 solder bumps 809 prior to placement on the routing layer 763 so as to increase heat conduction across the C4 connection layer 755.

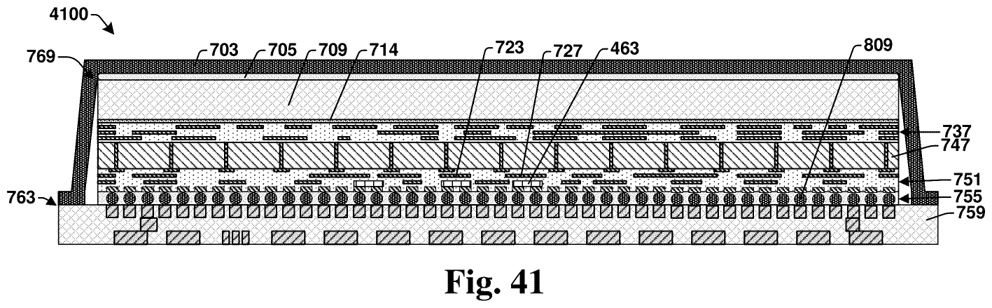

As shown by the cross-sectional view 4100 of FIG. 41, a thermal interface material 705 may be applied over the carrier substrate 709 and then the lid 703 may be attached. The thermal interface material 705 increases heat transfer to the lid 703 and the lid 703 helps dissipate heat to a surrounding environment. The lid 703 may be a metal or other material with similarly high thermal conductivity.

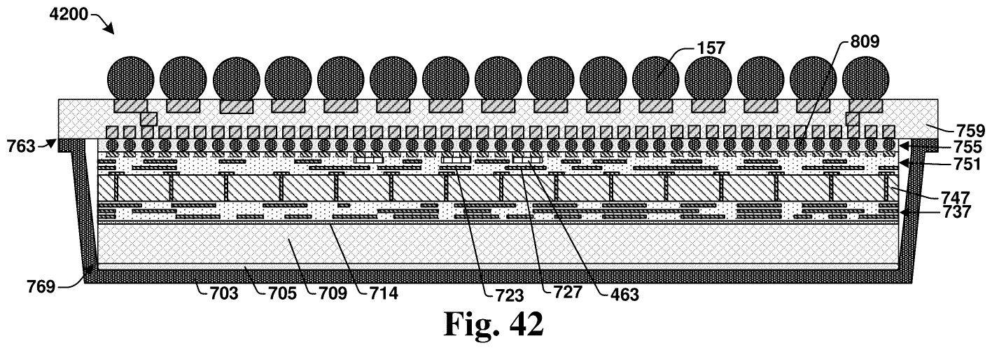

As shown by the cross-sectional view 4200 of FIG. 42, the solder bumps 157 may be placed on the routing layer 763 to provide the solder connection layer 145. The solder connection layer 145 may be used to attach the partially manufactured device shown in the cross-sectional view 4200 of FIG. 42, to a printed circuit board 147 to provide an apparatus such as the apparatus 701 of FIG. 7. The thermal paste 143 may be placed around the solder bumps 157 to increase heat transfer from the routing layer 763 to the printed circuit board 147 (see FIG. 7).

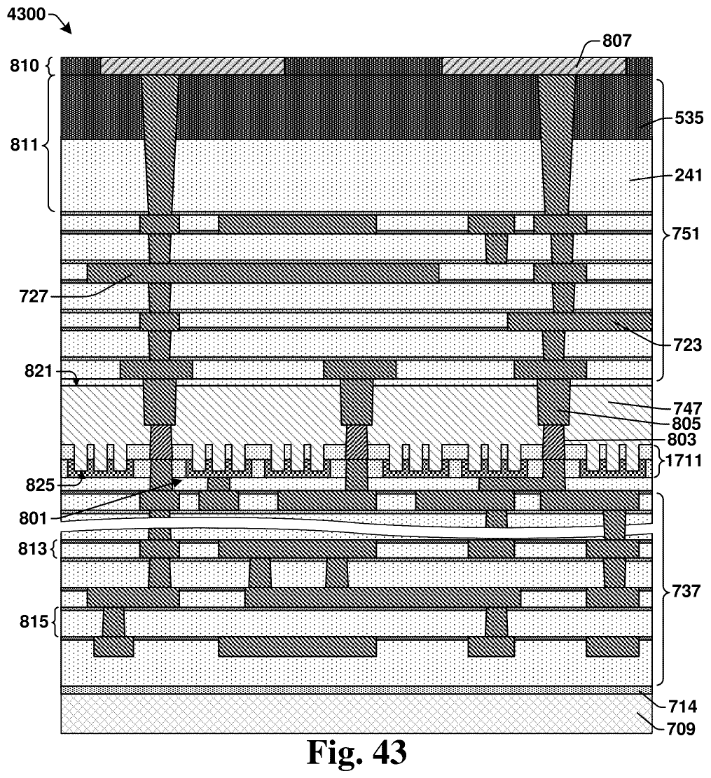

FIGS. 43-46 illustrate a variation of the foregoing process. This variation may be used to form an IC device such as the IC device 1001 of FIG. 10 in which the TEC 463 is in the C4 connection layer 755 rather than in the back side metal interconnect structure 751 (compare FIGS. 7 and 10)

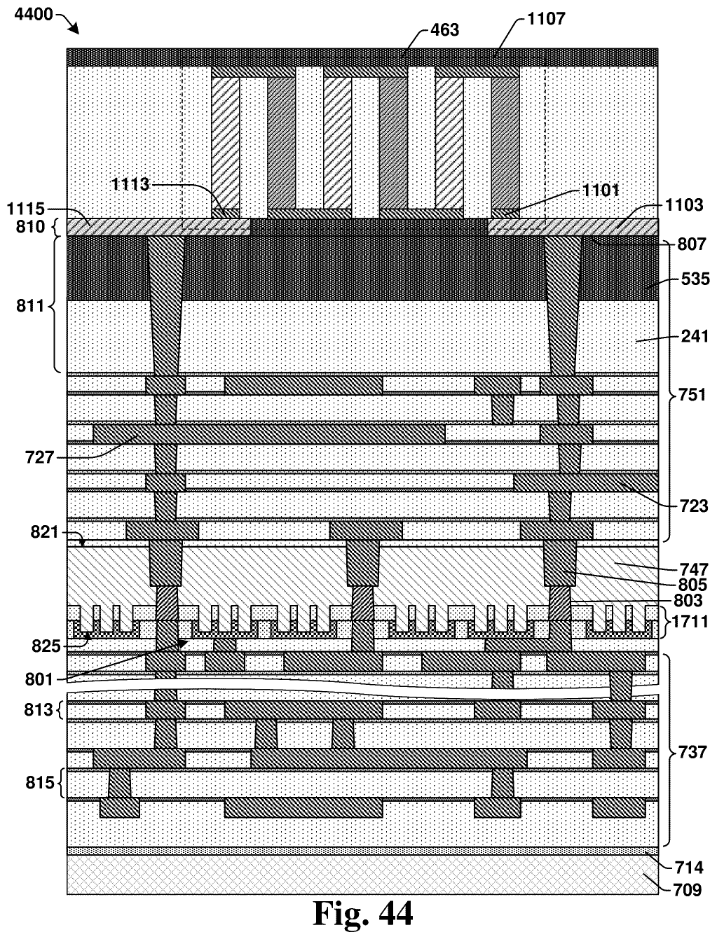

As shown by the cross-sectional view 4300 of FIG. 43 the process steps may begin with the steps shown in FIGS. 13-23 and 35-38 so that a device like the one shown by the cross-sectional view 3800 of FIG. 38 is produced except for the formation of the TEC 463 in the passivation stack 811 (compare FIG. 38). As shown by the cross-sectional view 4400 of FIG. 44. The processing of FIGS. 24-34 is then carried out so that the TEC 463 is formed over the pad layer 810.

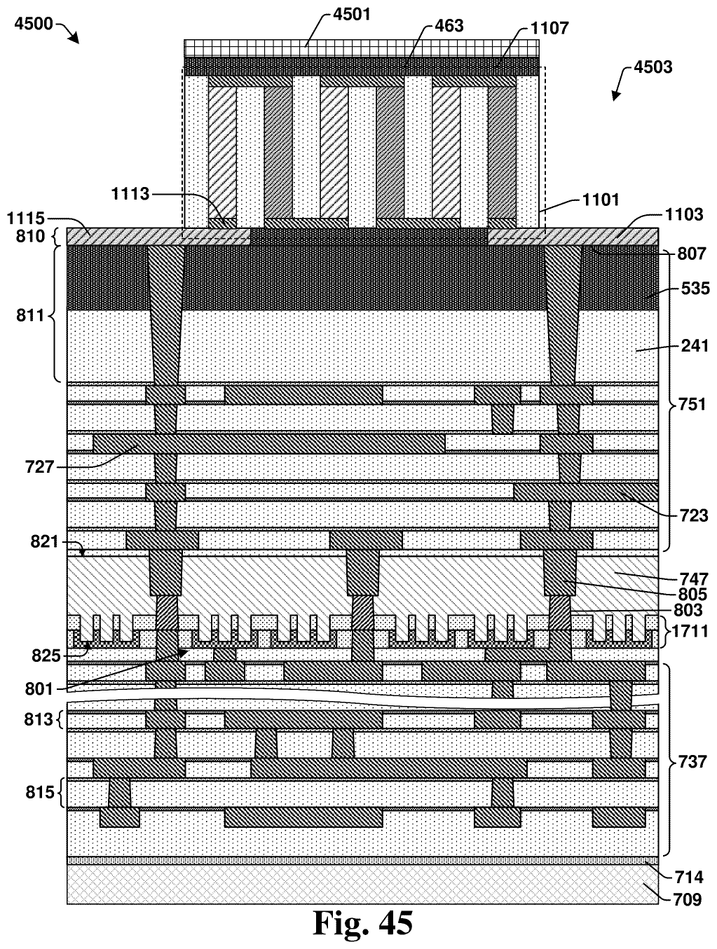

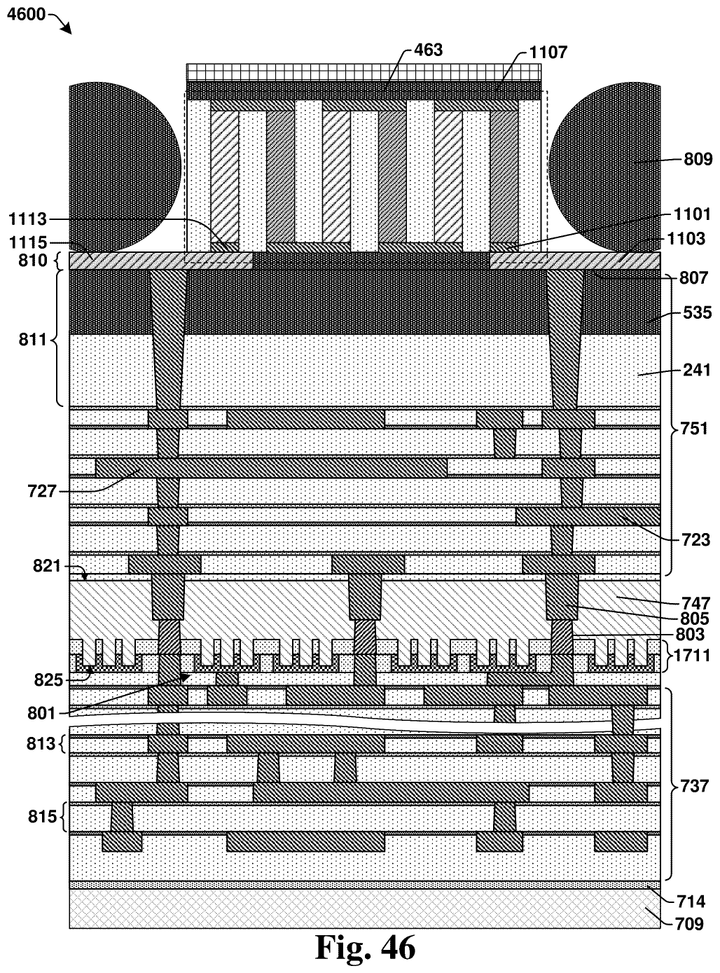

As shown by the cross-sectional view 4500 of FIG. 45, a mask 4501 may then be formed and used to etch through the high thermal conductivity dielectric 1107 and the oxide layer 241 to create openings 4503. As shown by the cross-sectional view 4600 of FIG. 46, the C4 solder bumps 809 may be placed in the openings 4503. In these embodiments, the TECs 463 may have heights similar to the C4 solder bumps 809. In some embodiments, the C4 solder bumps 809 have heights in the range from about 10 microns to about 100 microns. A plurality of TECs 463 may be stacked together to achieve this height.

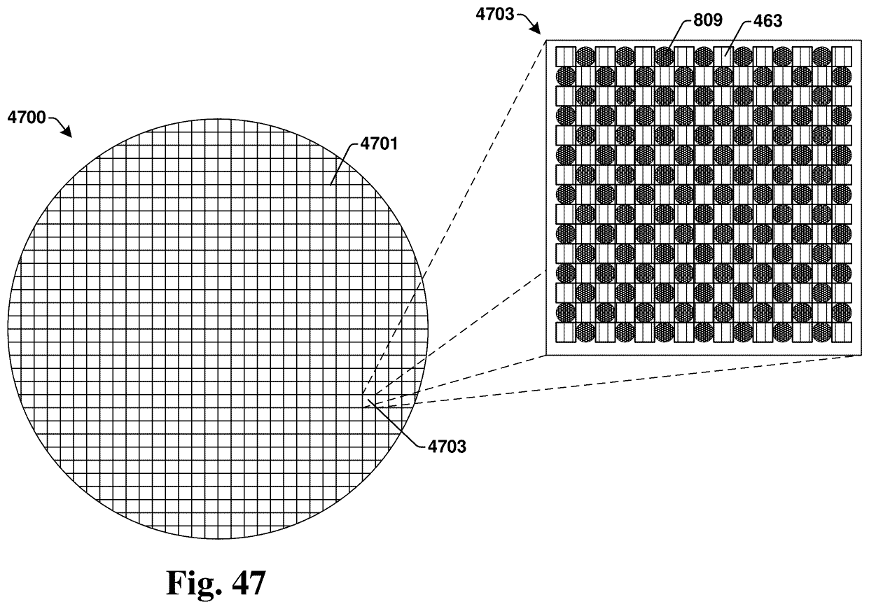

Up to and including the placement the C4 solder bumps 809, the semiconductor substrate 747 may be in the form of a wafer 4700, which is illustrated in FIG. 47. The wafer 4700 includes scribe lines 4701 that divide the wafer 4700 into a plurality of dies 4703. As shown in the expanded portion of FIG. 47, each die 4703 may include a plurality of TECs 463 interspersed within an array of the C4 solder bumps 809. The wafer 4700 may be divided into dice by cutting along the scribe lines 4701 after placement of the C4 solder bumps 809. After dicing, processing may continue as shown by the cross-sectional views 4000-4200 of FIG. 42-44. If desired, the wafer 4700 may be divided into dice before placement of the C4 solder bumps 809.

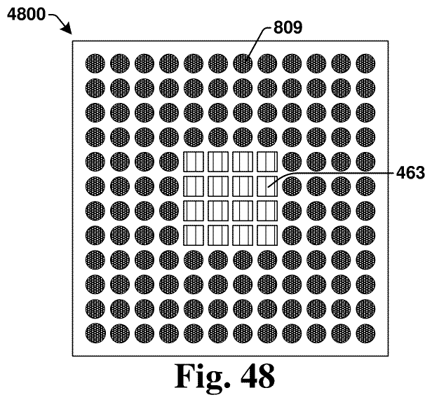

The C4 solder bumps 809 and the TECs 463 may have any suitable arrangement in the C4 connection layer 755 (see FIG. 10). FIG. 48 provides a plan view of a die 4800 in which the TECs 463 are grouped in the center and the C4 solder bumps 809 are arranged around the periphery. The TECs 463 grouped in the center may be united into one TEC 463 that is wider than any of the C4 solder bumps 809.

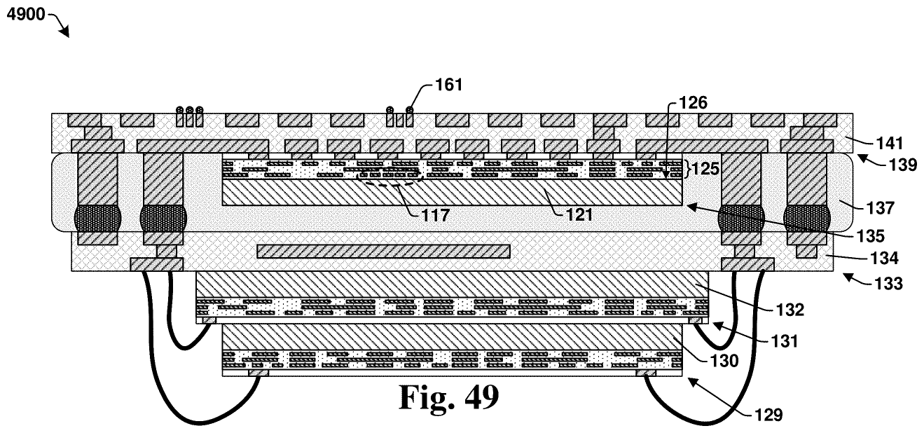

The foregoing processes provide IC devices with TECs that may be formed during wafer-level processing. FIGS. 49-51 illustrate a process in which separately manufactured TECs are integrated into a 3D-IC package.

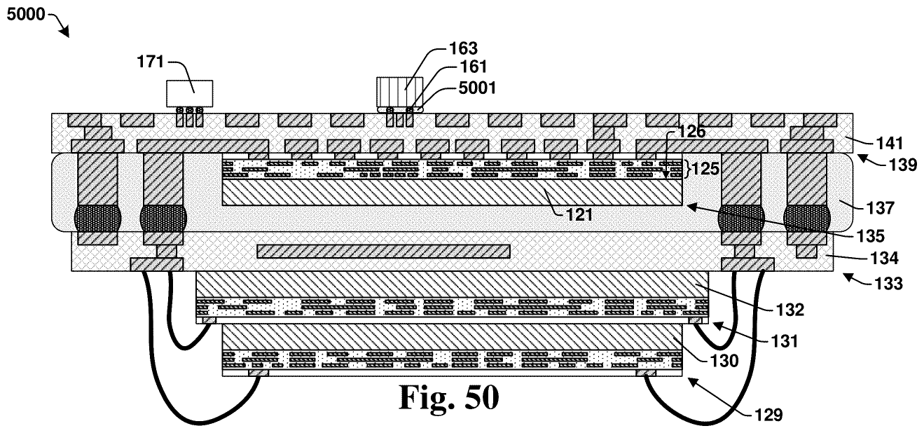

As shown by the cross-sectional view 4900 of FIG. 49, the process may begin with placement of solder micro-bumps 161 on the first routing layer 139. As shown by the cross-sectional view 5000 of FIG. 50, a TEC 163 may be placed on the first routing layer 139 and connected to the first routing layer 139 through the solder micro-bumps 161. Thermal paste 5001 may be applied to increase heat transport from the first routing layer 139 to the TEC 163. A passive device 171 may also be placed on the first routing layer 139 and connected to the first routing layer 139 through the solder micro-bumps 161 at this stage of processing.

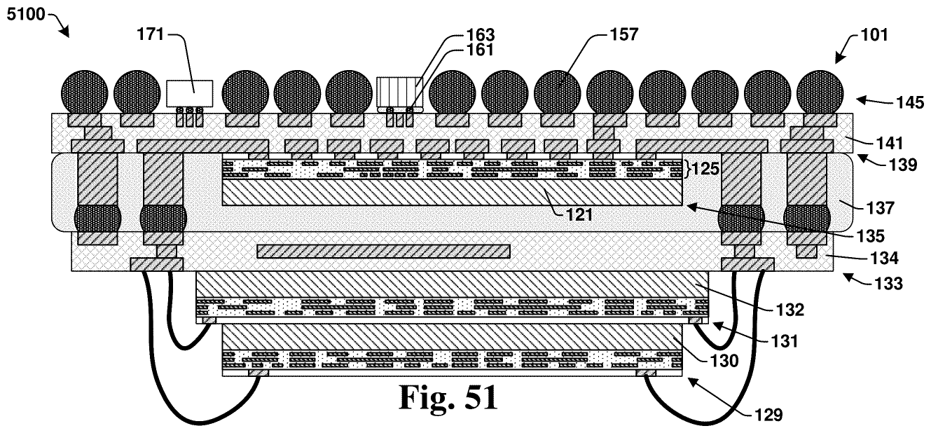

As shown by the cross-sectional view 5100 of FIG. 51, solder bumps 157 may be placed on the first routing layer 139 adjacent to or around the TEC 163 so as to form a BGA in the solder connection layer 145. The thermal paste 143 may be applied around the solder bumps 157. The structure shown by the cross-sectional view 5100 of FIG. 51 corresponds to the 3D-IC device 101 of FIG. 1. The 3D-IC device 101 may be attached to the printed circuit board 147 to produce the apparatus 100 of FIG. 1.

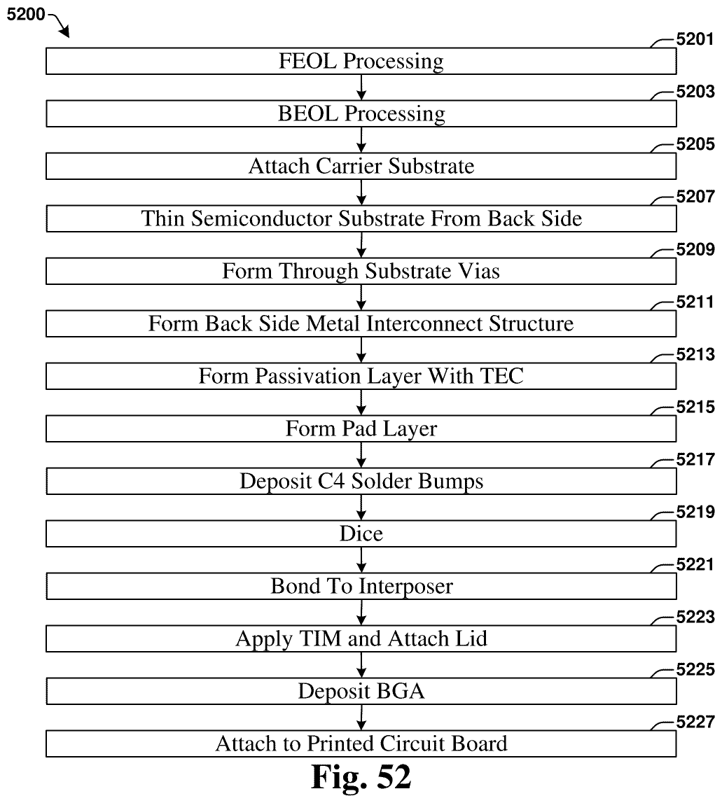

FIG. 52 provides a flow diagram for a method 5200 of forming an apparatus comprising an IC device. While the method 5200 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 5200 may begin with act 5201, FEOL processing of a semiconductor substrate. In some embodiments, this includes formation of a buried rail. The cross-sectional views 1300-1700 of FIGS. 13-17 provide an example.

The method may continue with act 5203, BEOL processing. BEOL processing forms a metal interconnect structure on the front side of the semiconductor substrate. The cross-sectional view 1800 of FIG. 18 provides an example.

Act 5205 is attaching the semiconductor substrate to a carrier substrate. The connection is formed through the metal interconnect structure so that the carrier substrate is on the front side of the semiconductor substrate. The cross-sectional view 1900 of FIG. 19 provides an example.

Act 5207 is thinning the semiconductor substrate from the back side. The cross-sectional view 2000 of FIG. 20 provides an example.

Act 5209 is forming TSVs through the thinned semiconductor substrate from the back side. The cross-sectional views 2100-2200 of FIGS. 21-22 provide an example.

Act 5211 is forming a back side metal interconnect structure up to a point before formation of the passivation layer. The cross-sectional view 2300 of FIG. 23 provides an example.

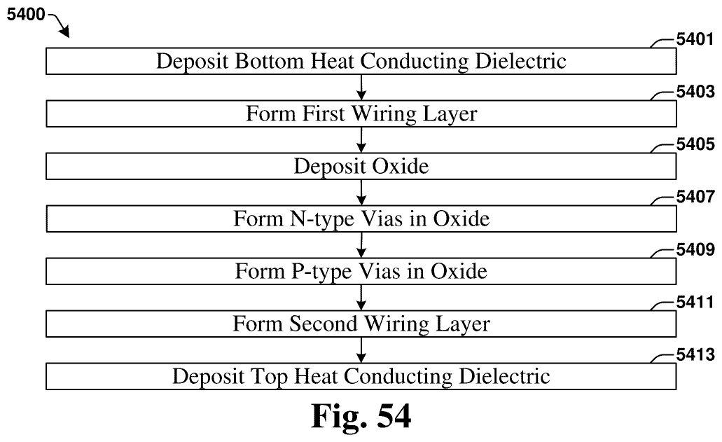

Act 5213 is forming a passivation layer over back side metal interconnect structure with a TEC. The cross-sectional views 2400-3700 of FIGS. 24-37 provide an example. The process of forming the TEC will subsequently be described with greater detail in connection with the method 5400 of FIG. 54.

Act 5215 is forming a pad layer over the passivation layer. The cross-sectional view 3800 of FIG. 38 provides an example.

Act 5217 is depositing C4 solder bumps on the pad layer. The cross-sectional view 3900 of FIG. 39 provides an example.

Act 5219 is dicing the partially manufactured semiconductor device. Up to this point, the semiconductor substrate is in the form of a wafer. FIG. 47 illustrates a plan view of a wafer showing the locations of scribe line along which the wafer is diced.

Act 5221 is bonding to an interposer through C4 solder connections. The cross-sectional view 4000 of FIG. 40 provides an example.

Act 5223 is applying a thermal interface material and attaching a lid. The cross-sectional view 4100 of FIG. 41 provides an example.

Act 5225 is placement of a BGA. The cross-sectional view 4200 of FIG. 42 provides an example. Act 5227 is attachment to a printed circuit board through the BGA.

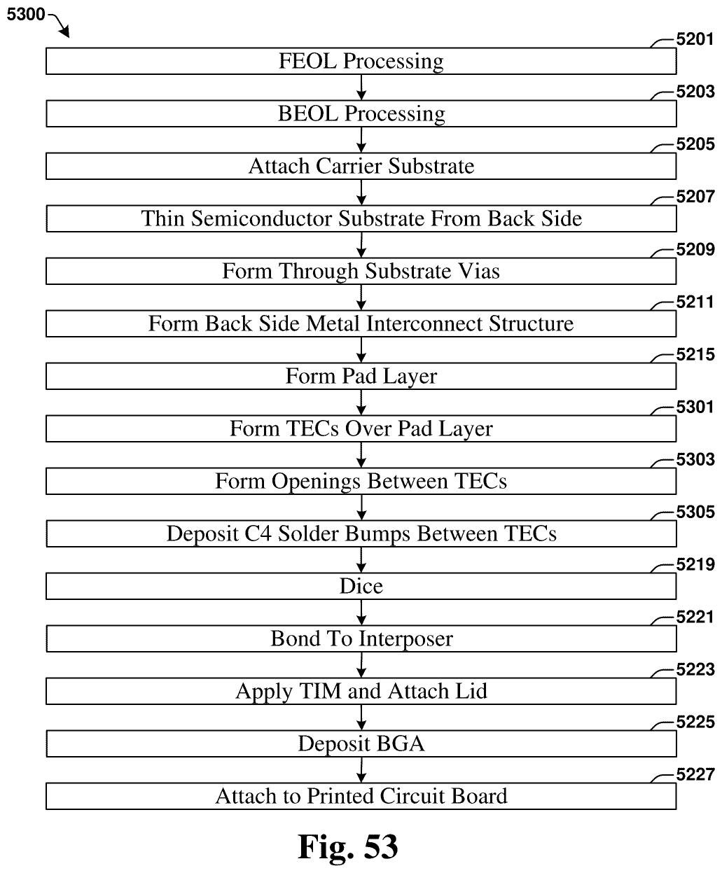

FIG. 53 provides a flow diagram for a method 5300. The method 5300 is the same as the method 5200 of FIG. 52 through act 5215, formation of the pad layer, except that in the method 5300 the actions that form the TEC within the passivation stack of the back side metal interconnect structure are deferred. The cross-sectional view 4300 of FIG. 43 provides an example of the resulting structure.

The method continues with act 5301, formation of the TEC over the pad layer. The steps of this process may be the same as those used to form the TEC in the method 5200 of FIG. 52. The cross-sectional view 4400 of FIG. 44 provides an example.

Act 5303 is masking and etching through the layer that contain the TEC so as to form openings. The cross-sectional view 4500 of FIG. 45 provides an example. Act 5305 is placing C4 solder bumps in the openings. The cross-sectional view 4600 of FIG. 46 provides an example. The method 5300 may then proceed in the same way as the method 5200.

FIG. 54 provides a flow diagram for a method 5400 of forming a TEC. The method 5400 may be performed during wafer-level processing.

The method 5400 begins with act 5401, forming a bottom heat conducting dielectric layer. In some embodiments, the dielectric is a high thermal conductivity dielectric. In some embodiments, the dielectric is an extremely high thermal conductivity dielectric. The cross-sectional view 2400 of FIG. 24 provides an example.

Act 5403 is forming the first wiring layer. The cross-sectional views 2400-2600 of FIGS. 24-26 provide an example.

Act 5405 is depositing an oxide layer. The oxide layer has low thermal conductivity. The cross-sectional view 2700 of FIG. 27 provides an example.

Act 5407 is forming N-type vias in the oxide layer. The cross-sectional views 2800-2900 of FIGS. 28-29 provide an example.

Act 5409 is forming P-type vias in the oxide layer. The cross-sectional views 3000-3100 of FIGS. 30-31 provide an example. The order of act 5407 and act 5409 may be reversed without consequence.

Act 5411 is forming the second wiring layer. The cross-sectional views 3200-3400 of FIGS. 32-34 provide an example.

Act 5413 forming a top heat conducting dielectric layer. In some embodiments, the dielectric is a high thermal conductivity dielectric. In some embodiments, the dielectric is an extremely high thermal conductivity dielectric. The cross-sectional view 3500 of FIG. 35 provides an example.

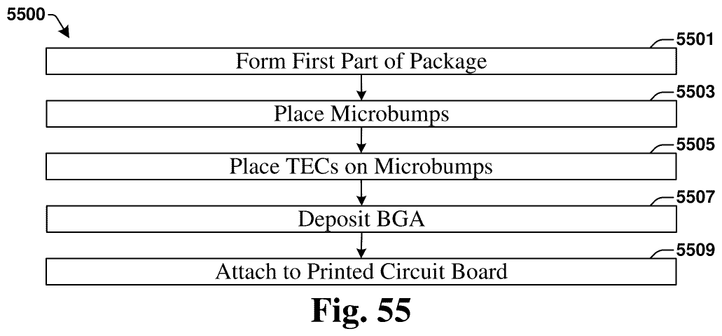

FIG. 55 provides a flow diagram for a method 5500 of forming an IC device. While the method 5500 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

The method 5500 begins with act 5501, forming a first part of an IC package. The IC package include at least one IC chip with a semiconductor substrate. Act 5503 is placing solder micro-bumps on one of the device layers in the package. The cross-sectional view 4900 of FIG. 49 provides an example.

Act 5505 is placing at least one TEC on the micro-bumps. Passive devices may be placed on other micro-bumps during this same stage of processing. The cross-sectional view 5000 of FIG. 50 provides an example.

Act 5507 is placing solder bumps to form a BGA in the device layer that contains the TEC. The solder bumps may be placed around the TEC. The cross-sectional view 5100 of FIG. 51 provides an example.

Act 5509 is connecting the IC package to a printed circuit board through the BGA. The apparatus of FIG. 1 provides an example of the resulting structure.

Some aspects of the present disclosure relate to an apparatus having an integrated circuit (IC) device and a thermoelectric cooler between a dielectric substrate and a semiconductor substrate. The thermoelectric cooler (TEC) is configured to transfer heat from the semiconductor substrate to the dielectric substrate. In some embodiments all or part of the TEC is within a passivation stack at the top of a first metal interconnect structure disposed on a first side of the semiconductor substrate. In some embodiments the passivation stack comprises a layer of an extremely high thermal conductivity dielectric. In some embodiments there is a lid over the semiconductor substrate. The lid covers a side of the semiconductor substrate opposite from the dielectric substrate. In some embodiments, the dielectric substrate is a printed circuit board.

In some embodiments a semiconductor device and a second metal interconnect are disposed on an opposite side of the semiconductor substrate. A through substrate via forms a connection between a power rail in the first metal interconnect structure and the semiconductor device. In some embodiments, a buried rail is disposed in the semiconductor substrate proximate the first side and the TSV connects to the buried rail.

Some aspects of the present disclosure relate to an integrated circuit (IC) device comprising a substrate having soldering connections over a the first side and a TEC in a layer with the solder connections so that the TEC is lateral to the solder connections. The TEC is configured to pump heat away the first substrate. In some embodiments, the TEC comprises a high thermal conductivity dielectric layer. In some embodiments, the TEC comprises an extremely high thermal conductivity dielectric layer. In some embodiments, the TEC between two solder bumps among the solder connections. In some embodiments, the substrate is a wafer.

In some embodiments, the substrate has a first metal interconnect structure on the first side and a second metal interconnect structure on a second side, opposite the first side. A semiconductor device is disposed on the second side. A through substrate via in the substrate is connected to provide power from the first metal interconnect structure to the semiconductor device.

In some embodiments, a semiconductor substrate is bound to the second side of the first substrate and the solder connections comprise a BGA. In some embodiments, the BGA is between the first substrate and a printed circuit board.

Some aspects of the present disclosure relate to a method of manufacturing an integrated circuit (IC) device. The method includes forming a metallization layer over a substrate, forming a first connection layer over the metallization layer, wherein the first connection layer comprises first wires, depositing a dielectric layer over the first connection layer, patterning first holes in the dielectric layer, filling the first holes with a first semiconductor having P-type doping so as to form P-type vias, patterning second holes in the dielectric layer, filling the second holes with a second semiconductor having N-type doping so as to form N-type vias, conducting planarization, wherein planarization provides a planarized surface and the planarized surface comprises the dielectric layer, the P-type vias, and the N-type vias, and forming a second connection layer over the planarized surface, wherein the second connection layer comprises second wires. The first wires form first connections between the P-type vias and the N-type vias. The second wires form second connections between the P-type vias and the N-type vias.

In some embodiments, the method further includes forming a layer of high thermal conductivity dielectric over the second connection layer. In some embodiments, the second connection layer comprises a high thermal conductivity dielectric.

In some embodiments, a passivation stack and a pad layer are formed over the metallization layer and the dielectric layer is formed over the pad layer. In some embodiments the method further etching holes that extend through the dielectric layer and placing solder bumps in the holes.

In some embodiments the method further includes forming a semiconductor device on a second side of the substrate. In these embodiments, the substrate is a semiconductor substrate, and the second side is opposite the first side. A metal interconnect structure is formed on the second side. The semiconductor substrate is bonded to a carrier substrate through the metal interconnect structure. The semiconductor substrate is the thinned from the first side, after which a second metal interconnect structure comprising the metallization layer is formed. In some embodiments, the method further includes formed a buried rail in the second side, coupling the semiconductor device to the buried rail, and forming a through substrate via through which power may be provided to the buried rail. In some embodiments the semiconductor substrate is a wafer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An apparatus, comprising:
a semiconductor substrate, having a first side and a second side, wherein the second side is opposite the first side;
a dielectric substrate; and
a thermoelectric cooler between the dielectric substrate and the semiconductor substrate, wherein the thermoelectric cooler is configured to transfer heat from the semiconductor substrate to the dielectric substrate.

2. The apparatus of claim 1, further comprising a first metal interconnect structure disposed on the first side, wherein the first metal interconnect structure comprises a first plurality of metallization layers and a passivation stack, the passivation stack is over the first plurality of metallization layers, and at least part of the thermoelectric cooler is within the passivation stack.

3. The apparatus of claim 2, wherein the passivation stack comprises a layer of an extremely high thermal conductivity dielectric.

4. The apparatus of claim 2, further comprising:
a second metal interconnect structure comprising a second plurality of metallization layers, wherein the second metal interconnect structure is disposed on the second side;
a semiconductor device disposed on the second side;
a power rail in the first metal interconnect structure; and
a through substrate via in the semiconductor substrate and coupling the power rail to the semiconductor device.

5. The apparatus of claim 1, further comprising a lid over the semiconductor substrate, wherein the lid covers a side of the semiconductor substrate opposite from the dielectric substrate.

6. An integrated circuit (IC) device, comprising:
a first substrate having a first side and a second side, wherein the second side is opposite the first side;
solder connections over the first side; and
a thermoelectric cooler in a layer with the solder connections so that the thermoelectric cooler is lateral to the solder connections, wherein the thermoelectric cooler is configured to pump heat away the first substrate.

7. The IC device of claim 6, wherein the thermoelectric cooler comprises a high thermal conductivity dielectric layer.

8. The IC device of claim 6, wherein the thermoelectric cooler comprises an extremely high thermal conductivity dielectric layer.

9. The IC device of claim 6, wherein the solder connections comprise two solder bumps and the thermoelectric cooler is between the two solder bumps.

10. The IC device of claim 6, further comprising:
a first metal interconnect structure comprising a first plurality of metallization layers on the first side and a second metal interconnect structure comprising a second plurality of metallization layers on the second side;
a semiconductor device disposed on the second side; and
a through substrate via disposed in the first substrate and connected to provide power from the first metal interconnect structure to the semiconductor device.

11. The IC device of claim 6, further comprising:
a semiconductor substrate;
where the semiconductor substrate is bound to the second side; and
the solder connections comprise a ball grid array.

12. The IC device of claim 6, wherein the thermoelectric cooler comprises first vias of N-type semiconductor and second vias of P-type semiconductor connected in series.

13. A method of manufacturing an integrated circuit (IC) device, the method comprising:
forming a metallization layer over a first side of a substrate;
forming a first connection layer over the metallization layer, wherein the first connection layer comprises first wires;
depositing a dielectric layer over the first connection layer;
patterning first holes in the dielectric layer;
filling the first holes with a first semiconductor having P-type doping so as to form P-type vias;
patterning second holes in the dielectric layer;
filling the second holes with a second semiconductor having N-type doping so as to form N-type vias;
conducting planarization, wherein planarization provides a planarized surface and the planarized surface comprises the dielectric layer, the P-type vias, and the N-type vias; and
forming a second connection layer over the planarized surface, wherein the second connection layer comprises second wires;
wherein the first wires form first connections between the P-type vias and the N-type vias; and
the second wires form second connections between the P-type vias and the N-type vias.

14. The method of claim 13, further comprising forming a layer of high thermal conductivity dielectric over the second connection layer.

15. The method of claim 13, further wherein the second connection layer comprises a high thermal conductivity dielectric.

16. The method of claim 13, further comprising forming a passivation stack and a pad layer over the metallization layer, wherein the dielectric layer is formed over the pad layer.

17. The method of claim 16, further comprising:
etching holes that extend through the dielectric layer; and
placing solder bumps in the holes.

18. The method of claim 13, further comprising:
forming a semiconductor device on a second side of the substrate, wherein the substrate is a semiconductor substrate, and the second side is opposite the first side;
forming a metal interconnect structure on the second side;
bonding the semiconductor substrate to a carrier substrate through the metal interconnect structure; and
thinning the semiconductor substrate from the first side prior to forming the metallization layer on the first side.

19. The method of claim 18, further comprising:
forming a buried rail in the second side;
coupling the semiconductor device to the buried rail; and
forming a through substrate via through which power may be provided to the buried rail.

20. The method of claim 13, wherein the substrate is a wafer.
